(19) United States
(12) Patent Application Publication
(10) Pub. No.: US 2015/0049549 A1
(43) Pub. Date: Feb. 19, 2015

(54) NONVOLATILE SEMICONDUCTOR MEMORY DEVICE, MEMORY CONTROLLER, AND MEMORY SYSTEM

(71) Applicant: KABUSHIKI KAISHA TOSHIBA, Tokyo (JP)

(72) Inventor: Norichika ASAOKA, Kanagawa (JP)

(73) Assignee: KABUSHIKI KAISHA TOSHIBA, Tokyo (JP)

(21) Appl. No.: 14/189,929

(22) Filed: Feb. 25, 2014

(30) Foreign Application Priority Data
Aug. 13, 2013 (JP) 2013-168317

(51) Int. Cl. G11C 16/10

(52) U.S. Cl. CPC G11C 16/10
USPC 365/185.12; 365/185.11

(57) ABSTRACT

A nonvolatile semiconductor memory device includes a memory cell array that share a plurality of bit lines, each block unit including a plurality of memory cells for storing user data and at least one memory cell for storing flag data indicating whether the block unit is defective, and a control unit configured to read the flag data from a block unit during a read operation or a write operation on the block unit, and when the flag data indicates the block unit is defective, discontinue the read operation and the write operation on the block unit.

### CROSS-REFERENCE TO RELATED APPLICATION

This application is based upon and claims the benefit of priority from Japanese Patent Application No. 2013-168317, filed Aug. 13, 2013, the entire contents of which are incorporated herein by reference.

### FIELD

Embodiments described herein relate generally to a nonvolatile semiconductor memory device, a memory controller, and a memory system, which are capable of managing a defective area.

### BACKGROUND

In recent years, stacked semiconductor memories in which memory cells are stacked have been developed. BiCS (Bit Cost Scalable) flash memory is one example of a low-cost and large-capacity semiconductor memory.

### DESCRIPTION OF THE DRAWINGS

FIG. 1 is a conceptual block diagram of a nonvolatile semiconductor memory device according to a first embodiment and a memory controller that controls the device.

FIG. 2A is a plan view of a memory plane (plane) according to the first embodiment.

FIG. 2B is a plan view focusing on a block within the plane according to the first embodiment.

FIG. 3 is a conceptual diagram illustrating a threshold distribution of a memory cell according to the first embodiment.

FIG. 4 is a cross-sectional view of a sub-block according to the first embodiment.

FIGS. 5A and 5B are conceptual diagrams illustrating a defect in a block unit according to the first embodiment; FIG. 5A is an enlarged plan view of a block unit shown in FIG. 2B, and FIG. 5B is an enlarged cross-sectional view of FIG. 4.

FIG. 6 is a readout operation of data according to the first embodiment; (a) of FIG. 6 is a flow diagram illustrating operations of the memory controller, and (b) of FIG. 6 is a flow diagram illustrating operations of a state machine.

FIG. 7 is a write operation according to the first embodiment; (a) of FIG. 7 is a flow diagram illustrating operations of the memory controller, and (b) of FIG. 7 is a flow diagram illustrating operations of the state machine.

FIG. 8 is a flow diagram illustrating an erasing operation according to the first embodiment.

FIGS. 9A and 9B are diagrams illustrating operations during an erasing operation according to the first embodiment; FIG. 9A is a conceptual diagram during an erasing operation in a user memory area, and FIG. 9B is a conceptual diagram during an erasing operation in a flag area.

FIG. 10 is a plan view focusing on a block within a plane according to a modified example of the first embodiment.

FIG. 11 shows a readout operation according to the modified example of the first embodiment; (a) of FIG. 11 is a flow diagram illustrating operations of the memory controller, and (b) of FIG. 11 is a flow diagram illustrating operations of the state machine.

FIG. 12 shows a write operation according to the modified example of the first embodiment; (a) of FIG. 12 is a flow diagram illustrating operations of the memory controller, and (b) of FIG. 12 is a flow diagram illustrating operations of the state machine.

FIGS. 13A and 13B are conceptual diagrams of a monitor area (shaded portion of a plane) according to a second embodiment; FIG. 13A is a plan view of the plane, and FIG. 13B is an enlarged view of the shaded area of FIG. 13A.

FIG. 14 is a threshold distribution of a monitor cell according to the second embodiment.

FIG. 15 shows write operations according to the second embodiment; (a) and (b) of FIG. 15 are flow diagrams illustrating write operations, and (c) of FIG. 15 is a conceptual diagram of data writing.

FIG. 16 is a flow diagram illustrating a readout operation and a write verifying operation according to the second embodiment.

FIGS. 17A to 17C are conceptual diagrams of a monitor area (perspective view of a plane) according to a third embodiment; FIG. 17A is a plan view of the plane, FIG. 17B is an enlarged view of FIG. 17A, and FIG. 17C is a circuit diagram of an area shown by a thick frame in FIG. 17B.

FIG. 18 shows write operations according to the third embodiment; (a) of FIG. 18 is a flow diagram illustrating operations of the memory controller, and (b) of FIG. 18 is a flow diagram illustrating operations of the state machine.

FIGS. 19A to 19G are diagrams illustrating a nonvolatile semiconductor memory device according to a second modified example of the third embodiment; FIGS. 19A to 19G are conceptual diagrams illustrating arithmetic operations using readout data and expectation values.

FIG. 20 shows operations of the state machine according to the third embodiment; (a) of FIG. 20 is a flow diagram illustrating operations of the memory controller, and (b) of FIG. 20 is a flow diagram illustrating operations of the state machine.

FIG. 21 is a cross-sectional view of a memory string according to a fourth embodiment manufactured by one-time processing, and a conceptual diagram of data writing.

FIG. 22 is a cross-sectional view of the memory string according to the fourth embodiment manufactured by multiple-time processing, and a conceptual diagram of data writing.

### DETAILED DESCRIPTION

The present embodiments provide a nonvolatile semiconductor memory device capable of managing a defective area.

In general, according to one embodiment, there is provided a nonvolatile semiconductor memory device including a memory cell array including a plurality of block units that share a plurality of bit lines, each block unit including a plurality of memory cells for storing user data and at least one memory cell for storing flag data indicating whether the block unit is defective, and a control unit configured to read the flag data from a block unit during a read operation or a write operation on the block unit, and when the flag data indicates the block unit is defective, discontinue the read operation and the write operation on the block unit.

Hereinafter, the present embodiments will be described with reference to the accompanying drawings. In the following description, identical elements are given identical reference numerals and signs throughout the drawings. However, the drawings are merely schematic, and thus it should be noted that the relationship between thickness and planar dimensions, the ratio of the thicknesses of respective layers and the like are different from those in actual implementations. Therefore, specific thicknesses and dimensions have to be determined in consideration of the following description.

A nonvolatile semiconductor memory device according to the present embodiment is used for managing defect information of a group (for example, area surrounded by Xfer described later=block unit BU0 as an example) of memory cells in both of (1) during manufacturing and (2) after shipment.

A detailed description of time-ordered events is as follows.

(1) During manufacturing, the state of the group is ascertained in advance before shipment, and the state of the group (information indicating whether there are defects) is retained in flag areas disposed on both ends of the group.

(2) After shipment, the inside of the group, that is, a user memory area is provided with a monitor area for determining whether the user memory area is required to be refreshed, in addition to the flag area. In other words, the group is managed by writing the defect information in the monitor area within the user memory area together with write data, and checking the state of the information retained in the flag area and the monitor area.

Further, the group may be managed by checking the state of the write data stored in the user memory area, without being provided with the monitor area after shipment.

A nonvolatile semiconductor memory device 10 described below is controlled by a memory controller 20 (control circuit), and includes a set of the nonvolatile semiconductor memory device 10 and the memory controller 20. Hereinafter, such a configuration is called a first memory system. An example of the first memory system includes a SD™ card, a SSD or the like.

In addition, the first memory system is capable of being connected to an external host device (not shown), and a second memory system includes the first memory system and the host device. The semiconductor device operates in accordance with control by the host device.

### First Embodiment

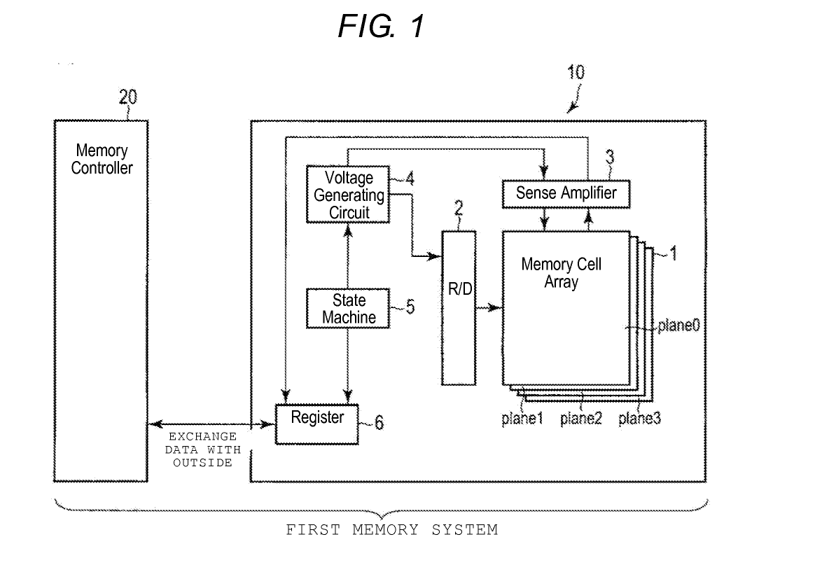

A first embodiment will be described with reference to FIG. 1. FIG. 1 is a conceptual block diagram of the first memory system according to the first embodiment.

The memory controller 20 controls the nonvolatile semiconductor memory device 10 described below. For example, a write operation, a readout operation, an erasing operation and the like are executed on the nonvolatile semiconductor memory device 10. In addition, the memory controller 20 transfers data to and from the nonvolatile semiconductor memory device 10 through the write operation, the readout operation and the like.

The nonvolatile semiconductor memory device 10 includes a memory cell array 1, a row decoder 2 (R/D), a sense amplifier 3, a voltage generating circuit 4, a state machine 5, and a register 6.

1. Configuration

1.1 Memory Cell Array 1

As shown in FIG. 1, the memory cell array 1 includes, for example, planes P0 to P3 (denoted as plane0, plane1, plane2, and plane3 in FIG. 1). The planes P0 to P3 include a plurality of memory cells MC which are sequentially stacked on the semiconductor layer. A memory string MS is constituted by the plurality of memory cells MC. As will be described later in detail, the memory string MS is electrically connected to a bit line BL and a source line CELSRC.

In addition, the planes P0 to P3 are given as an example, and there is no limit to the number of planes P contained in the memory cell array 1. When the planes P0 to P3 are not distinguished from each other, the plane is simply referred to as the plane P.

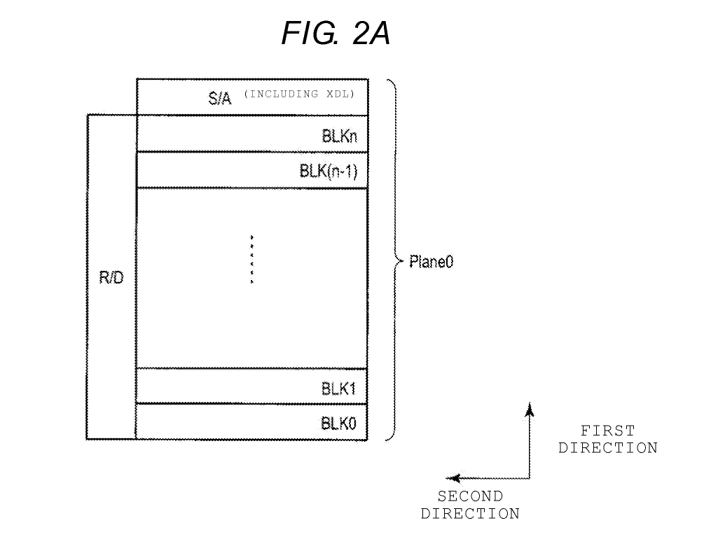

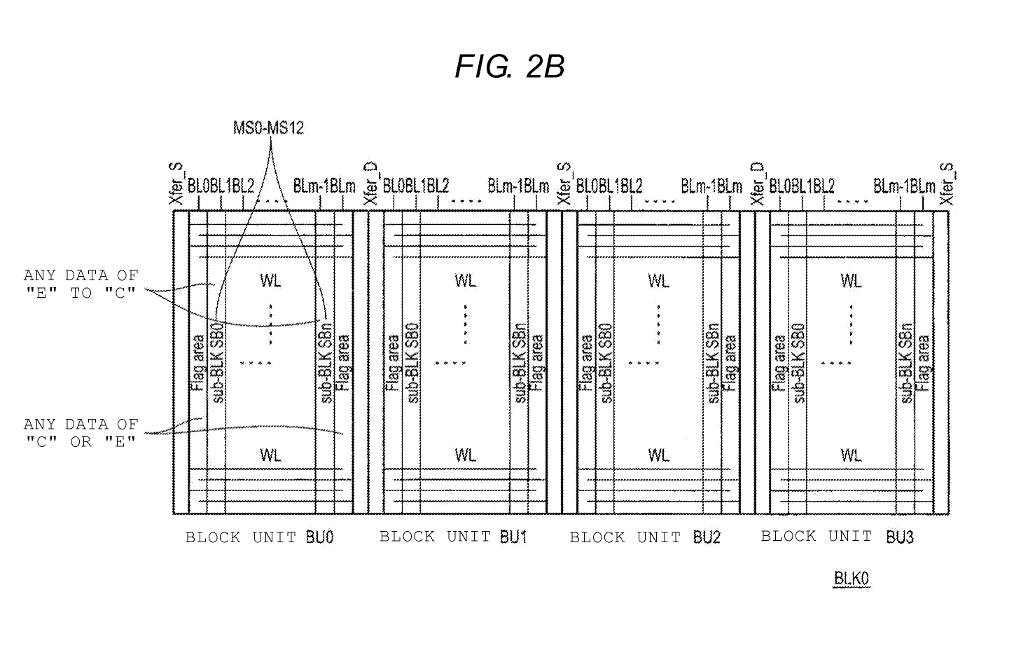

Next, further details of the plane P will be described with reference to FIGS. 2A and 2B. For the purpose of understanding, the plane will be described along with some of peripheral devices that control the plane P.

1.1.1 Plan View

Both FIGS. 2A and 2B are plan views. Specifically, FIG. 2A is a plan view illustrating the concept of the plane P0, and FIG. 2B is a plan view focusing on a block BLK0 within the plane P0.

As shown in FIG. 2A, Plane0 includes block BLK0 to block BLKn. Blocks BLK0 to BLKn have the same configuration, and thus a description will be given below focusing on block BLK0.

As shown in FIG. 2B, block BLK0 includes block units BU0 to BU3. Each of the block units BU0 to BU3 includes a plurality of sub-blocks SB (denoted as sub-BLK SB in the drawing), flag areas FA disposed on both ends of a sub-block SB0 and a sub-block SBn, and Xfer_S and Xfer_D, which are respectively a source side transfer transistor and a drain side transfer transistor.

The bit line BL extending in a first direction is disposed on each of the sub-blocks SB, and a plurality of word lines WL extending in a second direction are disposed thereon. For example, twelve memory strings MS are electrically connected to the bit line BL. The twelve memory strings MS make up the sub-block SB.

The same memory cells MC in all the memory strings MS within the block unit BU are connected to a common word line WL. Further details of the structure of the memory string MS will be described later. The number of memory strings MS is not limited to twelve, and the number thereof may increase or decrease.

For example, when the memory string MS includes memory cells MC0 to MC7, word lines WL0 to WL3 that are connected to each of the memory cells MC0 to MC3 and word lines WL4 to WL7 that are connected to each of the memory cells MC4 to MC7, are disposed in a comb-tooth shape.

In addition, a unit in which data is collectively read out is called a page. For example, referring to FIG. 2B, the term “page” as used herein means a group of memory cells MC in a string unit that are connected to the same word line WL.

When data is read out, data is read out in page units which also include the flag area FA. However, when user's data is written, data is written in a first unit that excludes bits included in the flag areas FA on both ends of a page.

In addition, Xfer_S and Xfer_D include switch circuits (MOS transistors). Each of these switch circuits is connected to the word line WL. That is, Xfer_S is connected to, for example, the word lines WL0 to WL3, and Xfer_D is connected to the remaining word lines WL4 to WL7. When the switch circuit is turned on, Xfer_S and Xfer_D transmit a predetermined voltage supplied from the voltage generating circuit 4 to these word lines WL.

The flag area FA (denoted as Flag area in the drawing) retains information on whether the block unit BU corresponding to the flag area FA is defective (hereinafter, defect information). This flag area FA has the same structure as that of the above sub-block SB, and includes a group of the memory string MS. That is, the defect information is retained by the memory cells MC of the memory string MS.

In addition, the defect information retained by the flag area FA is written before the nonvolatile semiconductor memory device 10 is shipped, and is an invariable value even after the shipment thereof. That is, the defect information is data which ought not to be erased, unlike user data which is retained by sub-block SB and may be erased as necessary. For this reason, the state machine 5 described later needs to perform predetermined control during the erasure of data so as not to erase the defect information.

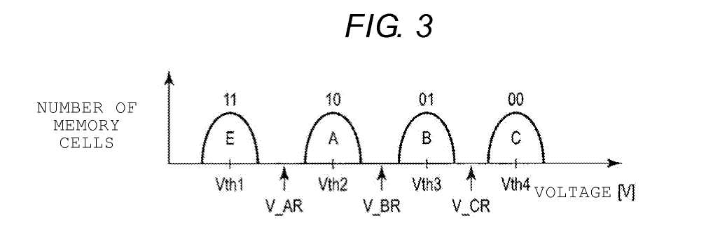

Hereinafter, the threshold distribution of the memory cell MC in the flag area FA and the user memory area will be described with reference to FIGS. 2B and 3.

1.1.1.1 Threshold Distribution

FIG. 3 is a conceptual diagram illustrating the threshold distribution of the memory cell MC (flag area FA and user memory area). This drawing is a graph of which the horizontal axis represents a threshold voltage and the vertical axis represents the number of memory cells MC.

As shown in the drawing, the memory cell MC can retain, for example, quaternary data (2-bit data).

That is, as also shown in FIG. 3, the memory cell MC in the user memory area can retain data having any of “E” level (“11”), “A” level (“10”), “B” level (“01”), and “C” level (“00”) in the ascending order of a threshold voltage Vth. Retention data associated with the threshold voltage Vth fluctuates with the injection of charge into a charge storage layer.

A threshold voltage Vth1 of “11” data in the memory cell MC represents an erase state, and has the relation of 0<Vth1<V_AR. That is, in the present embodiment, the erase state of the memory cell MC is located at the positive side. The erase state of the memory cell may have the relation of, for example, Vth1<0 without being limited to the positive side.

In addition, a threshold voltage Vth2 of “10” data has the relation of V_AR<Vth2<V_BR. A threshold voltage Vth3 of “01” data has the relation of V_BR<Vth3<V_CR.

Further, a threshold voltage Vth4 of “00” data has the relation of V_CR<Vth4. In this manner, the memory cell MC can retain 2-bit data having any of “11” to “00” data in accordance with a threshold.

On the other hand, as shown in FIG. 2B, the threshold distribution of the flag area FA in the block unit BU has either of the “C” or “E” level described later.

For example, when the block unit BU is defective, the threshold distribution of all of the memory cells MC in the flag area FA of this block unit BU is set to be in the above-mentioned “C” state.

When readout is performed on such a block unit BU in a case where the memory cell MC is defective, and the block BLK is defective for other reasons (for example, disconnection of word line WL), the data of the flag area FA is read out as data “C”. Therefore, “C” data is read even though the flag area FA has a defect so that the block unit BU is detected to be defective. In this manner, the flag area FA retains the “C” data in order to have uniformity with the defective memory cell MC. The above memory cell MC may be able to retain quaternary or more data.

In addition, for example, when the block unit BU is not defective, the threshold distribution of all the memory cells MC in the flag area FA is set to be in an erase state, that is “E”.

1.1.2 Cross-Sectional View

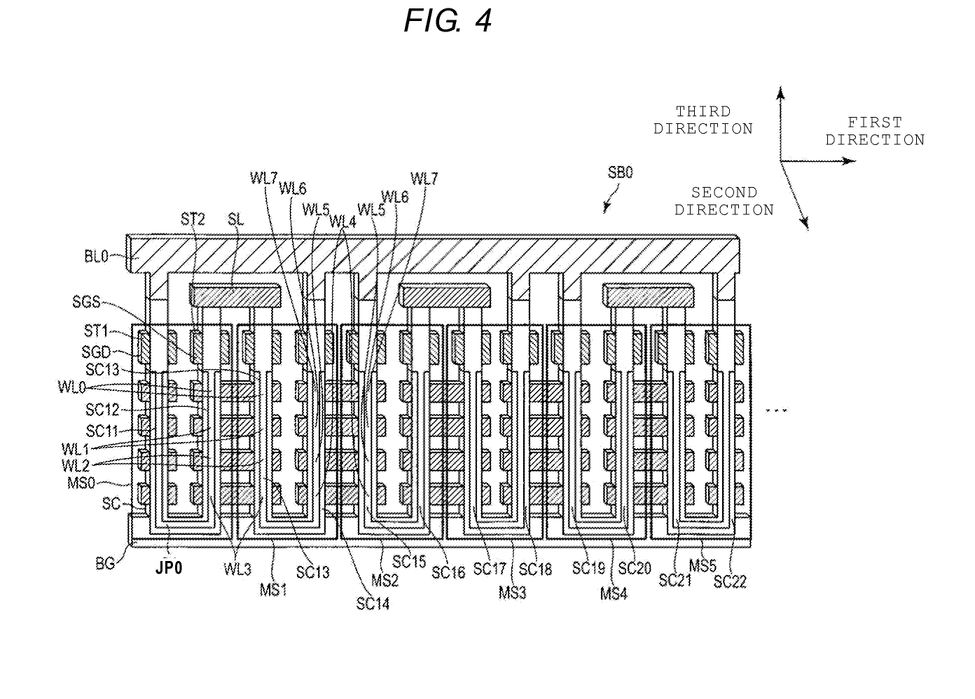

Next, FIG. 4 shows a cross-sectional view of the sub-block SB0 taken along line 4-4′ of FIG. 2B. The sub-block SB0 includes twelve memory strings MS, that is, memory strings MS0 to MS11, but the memory strings MS0 to MS6 are shown herein as an example.

1.1.2.1 With Respect to Memory Strings MS0 to MS5

As shown in FIG. 4, the memory strings MS0 to MS5 are provided along a cross-sectional direction.

In each of the memory strings MS, columnar semiconductor layers SC11 to SC22 are formed on a semiconductor layer BG, and toward a third direction perpendicular to the first direction and the second direction. Hereinafter, when the semiconductor layers SC11 to SC22 are not distinguished from each other, the semiconductor layer is simply called the semiconductor layer SC.

Next, the semiconductors layers SC adjacent to each other in the first direction are joined together through a joining portion JP provided within the semiconductor layer BG. For example, the semiconductor layers SC11 and SC12 are joined together through a joining portion JP0 within the semiconductor layer BG. With such a configuration, the U-shaped memory string MS0 is formed.

In addition, a set of the semiconductor layers SC13 and SC14, . . . , and a set of the semiconductor layers SC21 and SC22 also have the same configuration, and thus the description thereof will be omitted.

In addition, a plurality of polysilicon layers formed along the third direction are provided within each of the memory strings MS. Some of the polysilicon layers function as the word line WL, and the other polysilicon layers function as selection signal lines SGS and SGD.

The selection signal lines SGS and SGD are provided at positions with the word line WL interposed therebetween. That is, as shown in FIG. 4, when the number of word lines WL is set to four, the word lines WL3, WL2, WL1, and WL0, and the selection signal line SGS are stacked on the semiconductor layer BG in this order from below with an insulating film interposed therebetween. Similarly, the word lines WL4, WL5, WL6, and WL7, and the selection signal line SGD are stacked on the semiconductor layer BG in this order from below with an insulating film interposed therebetween.

Therefore, a selection transistor ST1, the memory cell MC7, the memory cell MC6, . . . , the memory cell MC1, the memory cell MC0, and a selection transistor ST2 are provided at points of the intersection of the semiconductor layer SC with the selection signal lines SGS and SGD and word line WL.

These selection signal lines SGS and SGD function as the selection signal lines SGS and SGD that control the selection and non-selection of the memory string MS.

1.1.2.2 With Respect to Bit Line BL and Source Line SL

One end of each of the selection signal lines SGD, the semiconductor layer SC11 and the semiconductor layer SC14, the semiconductor layer SC15 and the semiconductor layer SC18, and the semiconductor layers SC19 and SC22, that pass through the selection signal lines SGD, is respectively connected in common to the bit line BL0.

In addition, one end of each of the selection signal lines SGS, the semiconductor layers SC12 and SC13, the semiconductor layers SC16 and SC17, and the semiconductor layer SC20, that pass through the selection signal line SGS, is respectively connected in common to a source line SL. That is, for example, the semiconductor layers SC11 and SC12 and the semiconductor layers SC13 and SC14 which are adjacent to each other are connected in common through the source line SL.

1.1.2.3 With Respect to Bit Lines BL1 to BLm-1

In the above, a description is given focusing on the bit line BL0, but bit lines BL1 to BLm-1 also have the same configuration.

More generally, the semiconductor layer SC connected to a bit line BLi (i is a natural number, 1≦i≦m−1) is arranged for semiconductor layers SCi1 to SC(i+10). In this case, the selection signal line SGS, the word lines WL0 to 7, and the selection signal line SGD mentioned above pass through these semiconductor layers SCi1 to SC(i+10), and thus a plurality of memory strings MS are formed so as to correspond to each bit line BLi.

In each of the memory strings MS corresponding to the bit line BLi, the semiconductor layers SCi1 and SCi2 and the semiconductor layers SCi3 and SCi4 which are adjacent to each other are connected in common through the source line SL.

Here, a case where each of the memory strings MS is constituted by the memory cells MC0 to MC7 and the selection transistors ST1 and ST2 is described as an example, but the number of memory cells MC is not limited to 8. That is, the number of memory cells MC may be 16, and may be 32. The number of memory cells MC may be set to s (s is a natural number) as necessary.

In this manner, the plane P0 is formed by arraying the memory cells MC that electrically store data in a three-dimensional matrix. That is, the memory cells MC are arrayed in a lamination direction, and are also arrayed in a matrix in a horizontal direction perpendicular to the lamination direction. In this manner, a plurality of memory cells MC lined up in the lamination direction are connected in series, and the memory string MS is constituted by the plurality of memory cells MC connected in series.

1.2 Row Decoder 2

Returning back to FIG. 1, the configuration of the nonvolatile semiconductor memory device 10 will be described below. The row decoder 2 selects a word line WL within the memory cell array 1. Specifically, the row decoder 2 controls Xfer_S and Xfer_D in accordance with a block address BA, a row address RA, and a string address SA which are output by the memory controller 20. Xfer_S and Xfer_D function as a switch, and transmit a desired voltage to the selected word line WL. The voltage transmitted to the word line WL is supplied from the voltage generating circuit 4.

1.3 Sense Amplifier 3

The sense amplifier 3 selects a bit line BL in accordance with a column address CA which is output by the memory controller 20, and reads out data retained in the memory cell MC connected to the selected bit line BL during a readout. During a write, data is written in the memory cell MC connected to the selected bit line BL.

During the readout or write, the sense amplifier 3 transmits a desired voltage (for example, internal voltage VDD (=1.8 V), VSS (=0 V) or the like) to the selected bit line BL. The voltage VDD transmitted to the bit line BL is supplied from the voltage generating circuit 4.

In addition, the sense amplifier 3 inputs and outputs write data and readout data to and from the memory controller 20 through the register 6.

Further, the sense amplifier 3 temporarily retains the readout data in cache circuits and performs an arithmetic operation thereon, and then transmits the arithmetic operation results thereof to an XDL (not shown). The same is true of a read verifying operation after data writing.

1.4 Voltage Generating Circuit 4

The voltage generating circuit 4 generates a write voltage, a readout voltage, an erasing voltage and the like on the basis of the voltage VDD supplied from the outside, and then supplies the generated voltages to the row decoder 2.

Further details of the voltages generated by the voltage generating circuit 4 will be presented as necessary in the description of each operation.

1.5 State Machine 5

The state machine 5 controls the overall operations of the nonvolatile semiconductor memory device 10. Specifically, the state machine executes an operating sequence during a write operation, a readout operation, and an erasing operation of data, on the basis of a command from the memory controller 20.

The state machine 5 controls an operation of each circuit block included in the nonvolatile semiconductor memory device 10, in order to execute the sequence. For example, the state machine 5 controls the voltage control circuit 4 to generate a predetermined voltage, and controls the row decoder 2. In addition, the same is true of the bit line BL.

Further, the state machine 5 manages information on the defect of the block unit BU, and supplies the management information to the register 6.

Specifically, on the basis of defect information of the memory cell MC in the flag area FA or defect information of the memory cell MC provided within the user memory area, the state machine 5 maintains management data such as which block unit BU is defective or which block unit BU is required to be refreshed, in the register 6.

In addition, the state machine 5 may manage information on the defect of the block BLK, e.g., irretrievable information such as the disconnection of the word line WL, hole path open described later or the like, in which case the state machine 5 manages such a block BLK as a defective block.

A command received by the nonvolatile semiconductor memory device 10 may be issued from a host (not shown).

In addition, the state machine 5 manages the information on the defect of the block BLK and the block unit BU, but without being limited to this case, the state machine may manage, for example, information on the defect of the sub-block SB, and may supply the management information to the register 6.

1.6 Register 6

The register 6 retains the defect information of the block BLK, and supplies the information to the state machine 5 and the memory controller 20. In the following embodiment, a description will be given using the block unit BU.

2. Defective Block Unit BU

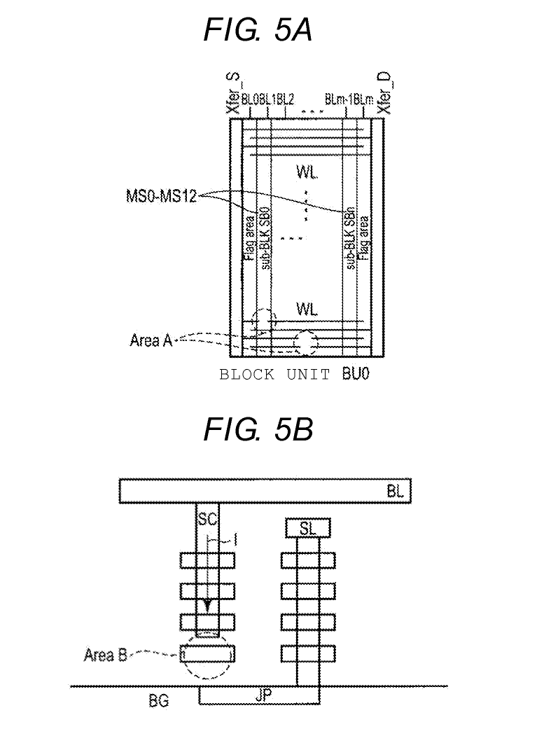

Next, a defective block unit BU will be described with reference to FIGS. 5A and 5B. When the block unit BU is defective as mentioned above, the flag area FA within the block unit BU retains “C” data. The state machine 5 determines whether the block unit BU is defective on the basis of data which is read out from the flag area FA, but an example in which the state machine 5 determines the block unit BU to be defective is shown as the following two patterns.

(Case A): Word Line WL Open (equivalent to FIG. 5A)

(Case B): Hole Path Open (equivalent to FIG. 5B)

Although not shown herein, the block unit BU is determined to be defective even in the case of a short between memory holes other than the one described herein.

2.1 Case of FIG. 5A

FIG. 5A is an enlarged plan view of the block unit BU shown in FIG. 2B. For example, in case A, the open defect of the word line WL occurs in an area A as shown in FIG. 5A.

Normal data readout can be performed without applying a voltage to the word line WL located on the side away from Xfer_S or Xfer_D. Therefore, in this case, the block unit BU surrounded by Xfer_S and Xfer_D becomes a defective area.

In FIG. 5A, the word lines WL connected to both Xfer_S and Xfer_D are in a disconnected state. However, even when only one of the word lines WL connected to Xfer_S is in a disconnected state, the state machine 5 determines the block unit BU to be defective in a range shown in FIG. 5A.

2.2 Case of FIG. 5B

FIG. 5B is an enlarged cross-sectional view of FIG. 4. For example, in case B, hole path open occurs in area B as shown in FIG. 5B.

In this case, since a current I from the bit line BL does not flow into the source line SL, readout cannot be performed, and thus the block unit BU becomes a defective area, and the range shown in FIG. 5A becomes a defective area.

3. Readout Operation

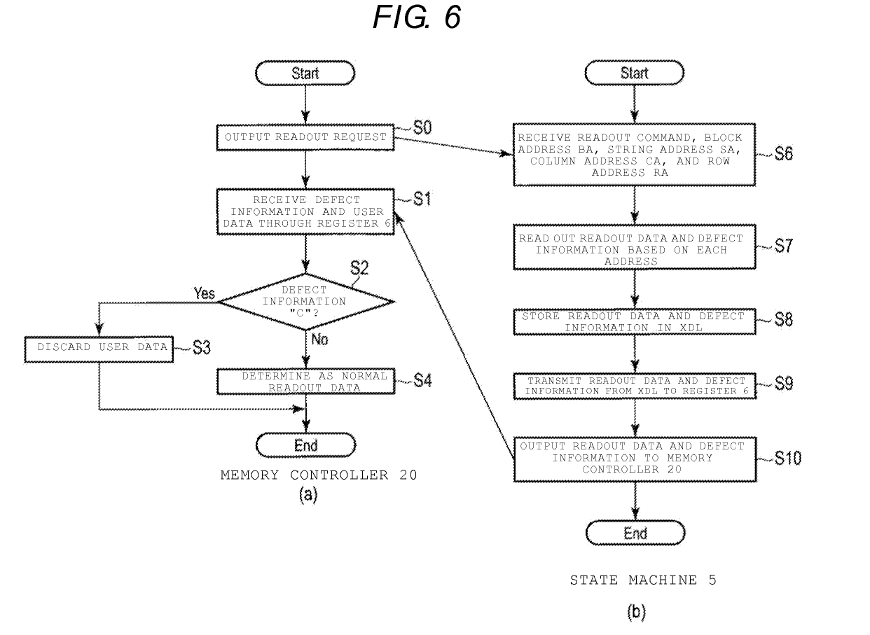

Next, readout operations of the first memory system will be described with reference to (a) and (b) of FIG. 6. That is, (a) and (b) of FIG. 6 are flow diagrams illustrating operations of the state machine 5 and the memory controller 20 during the readout operations.

The memory controller 20 is assumed not to retain information such as which block unit BU within the nonvolatile semiconductor memory device 10 is defective. That is, the memory controller 20 is assumed to determine defect information of the flag area FA for each readout operation.

3.1 Memory Controller 20

As shown in (a) of FIG. 6, the memory controller 20 outputs a readout command, the block address BA, the string address SA, and the row address RA (hereinafter, called a readout request) to the nonvolatile semiconductor memory device 10 (step S0).

Thereafter, both the user data and the defect information are received from the nonvolatile semiconductor memory device (S1). When it is determined that the received defect information is defective (“C” data) (S2, YES), the memory controller 20 discards the received user data (S3).

On the other hand, when the defect information is normal in step S2 (S2, NO), the user data transmitted from the nonvolatile semiconductor memory device 10 is determined to be normal readout data (S4).

3.2 State Machine 5

As shown in (b) of FIG. 6, when the readout request is issued from the memory controller 20 (S6), the state machine 5 reads out data (user data and defect information) in page units on the basis of the address (S7).

Further details of the application of a voltage to the bit line BL and the word line WL according to the readout operation are well-known, and thus the description thereof will be omitted.

Thereafter, the state machine 5 retains both the user data and the defect information, which are read out in step S7, in a cache circuit (XDL) within the sense amplifier 3 (S8).

Next, the state machine 5 temporarily retains both the user data and the defect information within the cache circuit (XDL) in the register 6 (S9), and then outputs the user data and the defect information to the memory controller 20 (S10).

In addition, the output of the defect information to the memory controller 20 by the state machine 5 is not limited to the readout operation. For example, when a command for knowing which block unit BU is defective is fetched, an operation may be performed in which the defect information is read out from the flag area FA, and is output to the memory controller 20.

In this case, the memory controller 20 manages which block unit BU is defective before the readout operation or the write operation is performed, and thus a readout operation and write operation are not carried out unnecessarily.

4. Write Operation

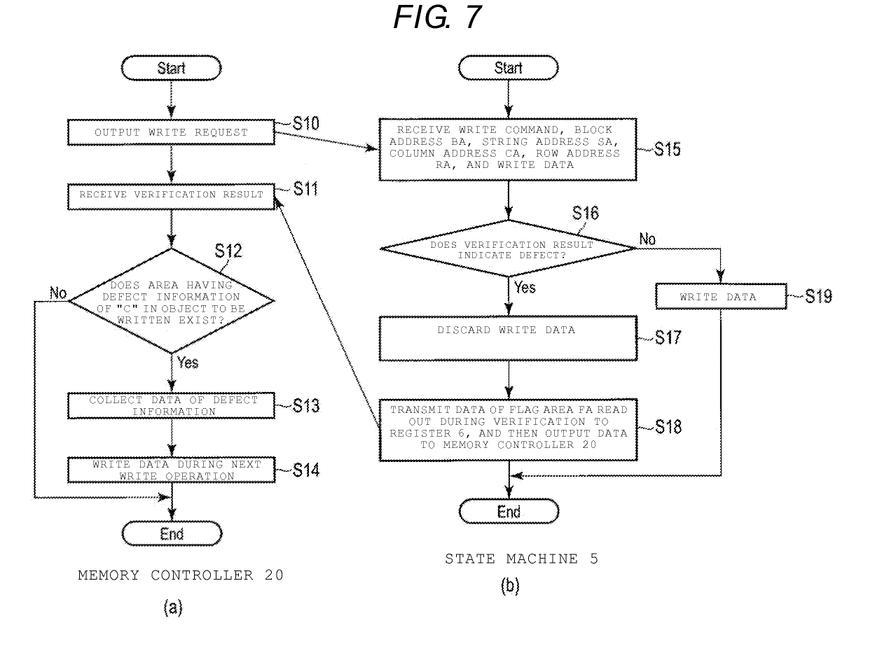

Next, a write operation and a write verifying operation according to the first memory system will be described with reference to (a) and (b) of FIG. 7. Meanwhile, (a) and (b) of FIG. 7 are flow diagrams illustrating a write operation and a write verifying operation.

4.1 Memory Controller 20

As shown in (a) of FIG. 7, the memory controller 20 outputs a write command, write data, the block address BA, the string address SA, and the row address RA (hereinafter, write request) to the nonvolatile semiconductor memory device 10 (S10).

Next, a verification result of the flag area FA received from the nonvolatile semiconductor memory device 10 is confirmed (S11). When the verification result indicates the defect (flag area FA retains “C” data) (S12, YES), the memory controller 20 collects defect information (S13).

Thereafter, write data which is output to the nonvolatile semiconductor memory device 10 in step S10 is retained, and the write data is written again during the next write operation (S14).

On the other hand, when the verification result does not indicate the defect (flag area FA retains “E” data; NO in S12), the write data transmitted in step S10 is determined to be normally written, and the write operation is terminated.

4.2 State Machine 5

Next, as shown in (b) of FIG. 7, when the write request is received from the memory controller 20 (S15), the state machine 5 executes a verifying operation with respect to the corresponding memory cell MC. Specifically, the state machine executes write verification (readout voltage is voltage V_AV) with respect to the memory cell MC in the flag area FA.

As a result, when the verification result indicates the defect (flag area FA retains “C” data) (S16, YES), the state machine 5 discards the write data received from the memory controller 20 (S17). In addition, when the verification result is good (flag area FA retains “E” data), data is written in the block unit BU of the flag area FA (S19).

Next, the state machine 5 transmits the verification result which is read out in step S16 to the register 6, and then outputs the verification result stored by the register 6 to the memory controller 20 (S18).

On the other hand, when the state machine 5 determines that the verification result in step S15 is not defective (flag area FA retains “E” data) (S16, NO), the state machine 5 writes the data (S19).

In step S16, the state machine 5 may write the data in another block BLK different from the address without discarding the write data.

Further details of the application of a voltage to the bit line BL and the word line WL according to the write verifying operation and the write operation are well-known, and thus the description thereof will be omitted.

4. Erasing Operation

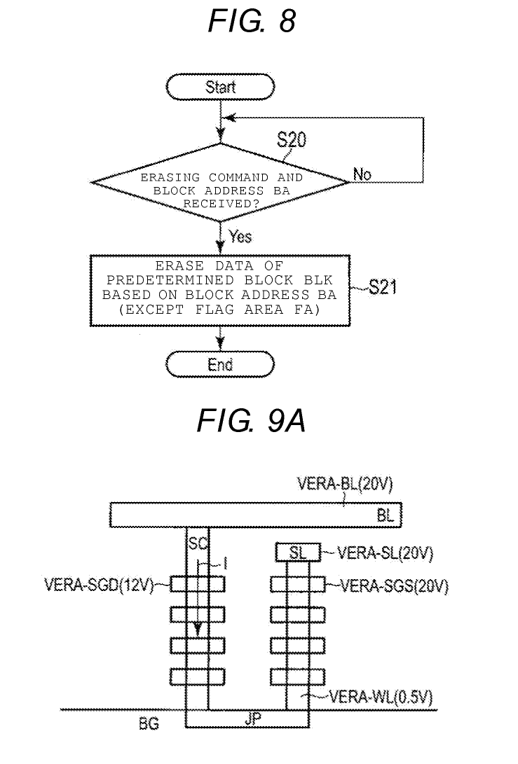

Next, an erasing operation according to the first memory system will be described with reference to FIG. 8. FIG. 8 is a flow diagram illustrating an erasing operation.

As shown in FIG. 8, when an erasing command and a block address BA to be erased are received from the memory controller 20 (S20, YES), the state machine 5 erases data retained in the memory cell MC constituting a predetermined block BLK on the basis of the block address BA (S21).

In this case, the state machine 5 needs to control a potential of the bit line BL so as not to erase the defect information retained by the flag area FA.

An erasure unit may be the block BLK, and may be the block unit BU. When erasure is performed in units of the block unit BU, the state machine 5 needs to receive the block address BA and the column address CA from a host.

4.1 Voltage Application Method

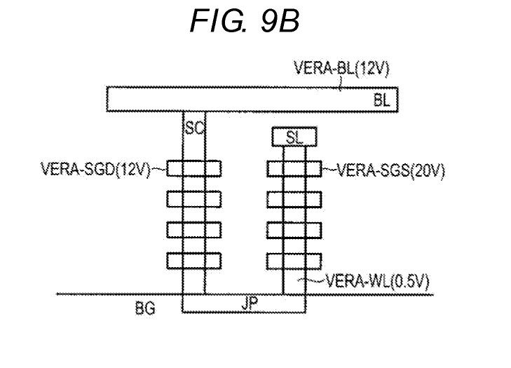

Next, an erasing voltage generated by the voltage generating circuit 4 during the erasing operation, and a voltage application method will be described with reference to FIGS. 9A and 9B.

FIG. 9A is an enlarged view of FIG. 4 and a conceptual diagram illustrating the application of a voltage during the erasing operation. In addition, FIG. 9B is an enlarged cross-sectional view of the memory string MS in the flag area FA, and is a conceptual diagram illustrating the generation of a voltage during the erasing operation.

First, a voltage which is controlled from the state machine 5 and is generated by the voltage generating circuit 4 will be described.

4.1.1 Erasing Voltage

When an erasing command is received, the state machine 5 generates voltage VERA_BL (for example, 20 V, or 12 V), voltage VERA_SL (for example, 20 V), voltage VERA_SGD (for example, 12 V), voltage VERA_SGS (for example, 20 V), and voltage VERA_WL (for example, 0.5 V) in the voltage generating circuit 4, and supplies these voltages to the word line WL, the bit line BL, and gates of the selection transistors ST1 and ST2 within the block unit BU.

4.1.1 FIG. 9A: With Respect to User Memory Area

As shown in FIG. 9A, GIDL is generated between the bit line BL (20 V) and the gate (12 V) of the selection transistor ST1, and holes flow in the direction of the source line SL until the potential of the semiconductor layer SC reaches approximately 20 V. For this reason, the generated holes are accumulated in the semiconductor layer SC, and a potential rises. That is, the potential of the semiconductor layer SC rises.

On the other hand, a voltage of approximately 0.5 V is applied to the word line WL. Therefore, electrons within the memory cell MC (charge storage layer) are discharged to the semiconductor layer SC due to a potential difference between the word line WL and the semiconductor layer SC. Thereby, the erasure of data is executed.

Here, the erasing operation in the user memory area is described. When the erasing operation is performed on the flag area FA similarly, the defect information disappears. That is, as shown in FIG. 9A, when GIDL is generated between the bit line BL and the gate of the selection transistor ST1, the defect information disappears. Consequently, the state machine 5 performs the following control as shown in FIG. 9B.

4.1.2 FIG. 9B: With Respect to Flag Area FA

As shown in FIG. 9B, a voltage VERA_WL is applied to all word lines within the memory unit BU. A voltage VERA_SGD is applied to all selection signal lines SGD within the memory unit BU. A voltage VERA_SGS is applied to all selection signal lines SGS within the memory unit BU.

Here, a voltage having the same value as voltage VERA_SGD applied to the gate of the selection transistor ST1 is applied to the bit line BL within the flag area FA. That is, the generation of GIDL is suppressed without generating a potential difference between the bit line BL and the selection transistor ST1. Thereby, the defect information retained by the flag area FA is prevented from being erased even during the erasing operation.

As mentioned above, in the structure of the memory cell array 1 according to the first embodiment, erasure/non-erasure can be controlled by the voltage transmitted to the bit line BL. Therefore, for example, a half block BLK (half page) can be erased. In this manner, when data can be managed by the half page, a method of higher flexibility can be used.

### Effect According to First Embodiment

In the first memory system according to the first embodiment, it is possible to obtain the effect of (1).

(1) it is Possible to Improve Relief Efficiency.

Even in a case of the open defect of the semiconductor layer SC without being limited to the open defect of the word line WL thus far, 1 block BLK is determined to be defective.

On the other hand, in the first embodiment, the block BLK is divided into a plurality of block units BU, and the flag area FA is disposed in units of the block unit BU (units separated by Xfer_S and Xfer_D).

When considering the size of the block BLK, the flag area FA does not cause a large increase of a circuit area. That is, relief efficiency can be improved without increasing a circuit area.

In this manner, the block BLK is divided into plural pieces, and thus an area which was not capable of being released for use can be released for use.

Specifically, in the first memory system according to the first embodiment, the flag area FA is disposed for each of a plurality of block units BU provided within the block BLK, and thus the size of each area managed by the state machine 5 is reduced. Therefore, when the block unit BU0, for example, within the block BLK0 is determined to be defective, and other block units BU1 to BU3 are good areas, these areas can be released for use.

As an example, the block is divided into four block units BU, but the block can also be constituted by more block units BU.

### Modified Example

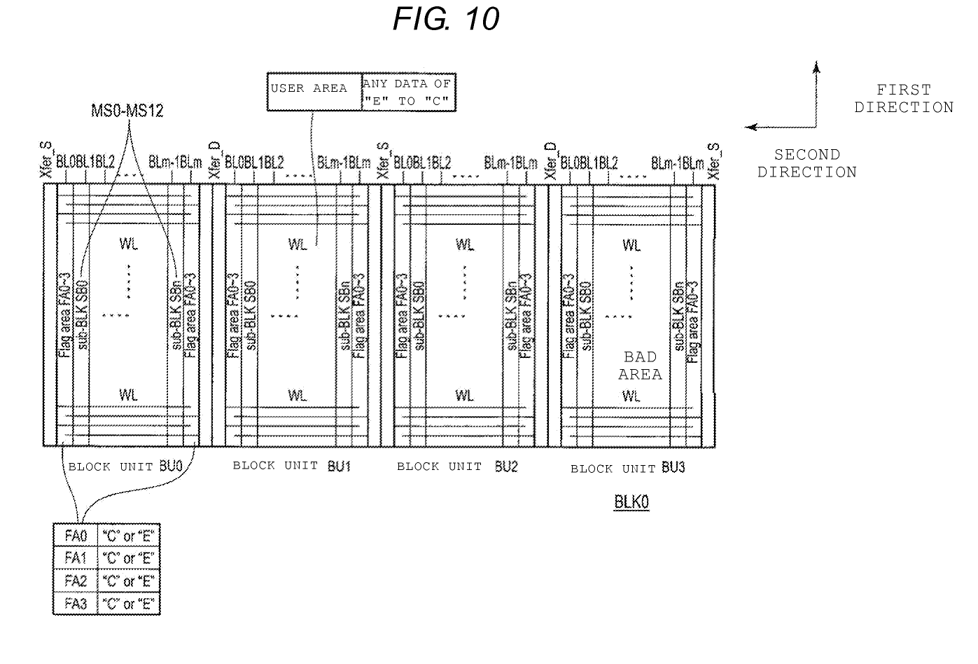

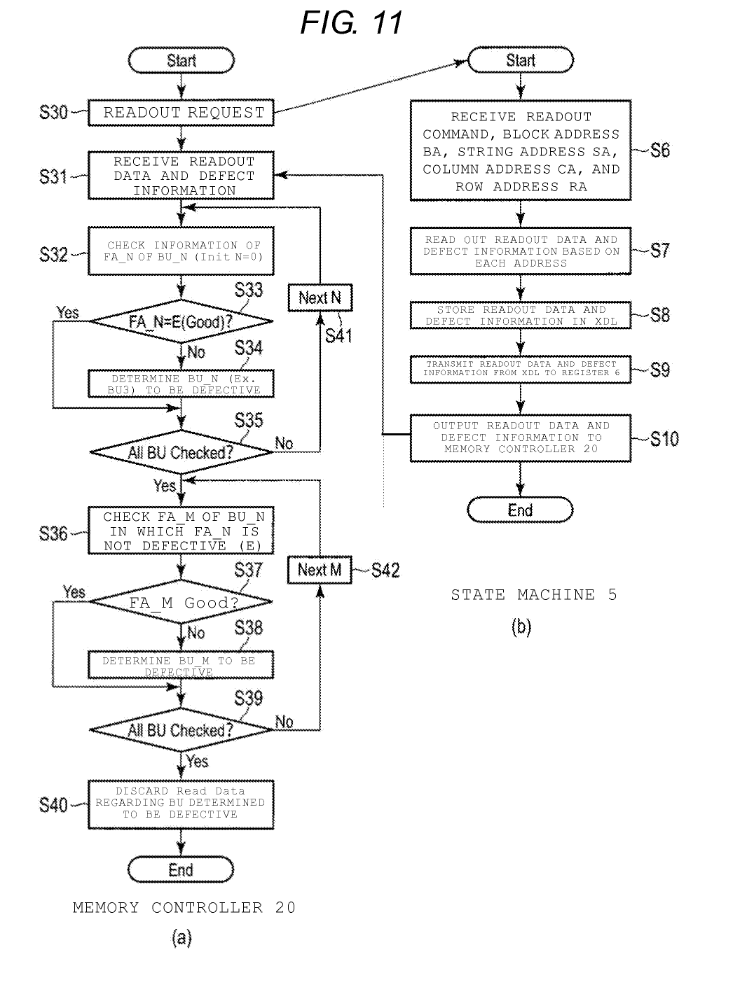

Next, a modified example according to the first embodiment will be described with reference to FIG. 10 and (a) and (b) of FIG. 11. The modified example is different from the above-mentioned embodiment, in that the flag area FA further retains defect information of another block unit BU. With the configuration according to the modified example, the reliability of a certain block unit BU having the defect is confirmed by the defect information of the flag area FA disposed in another block unit BU having no defect.

1. Configuration

FIG. 10 shows a plan view of the block BLK0 according to the modified example. As shown in the drawing, flag areas FA0 to FA3 are disposed on both ends of each of the block units BU0 to BU3 constituting the block BLK0.

Defect information corresponding to the block units BU0 to BU3 is retained in these flag areas FA0 to FA3. For example, when focusing on the block unit BU1, the flag areas FA0 to FA3 are disposed within the block unit BU1. That is, not only the flag area FA1 retaining the defect information corresponding to the block unit BU1, but also the defect information corresponding to other block units BU0, BU2, and BU3 within the block unit BU1 is retained in the flag areas FA0 to FA3.

Hereinafter, a description will be given by assuming the block unit BU3 to be defective (flag area FA=“C”, denoted as “defect area” in FIG. 10), and assuming the other BU0, BU1, and BU2 to be good areas (flag area FA=“E”).

2. Readout Operation

Next, a readout operation will be described with reference to FIG. 10 and (a) and (b) of FIG. 11.

Meanwhile, (a) of FIG. 11 is a flow diagram illustrating operations of the memory controller 20, and (b) of FIG. 11 is a flow diagram illustrating operations when the state machine 5 receives a readout command from the memory controller 20.

When the block address BA, the string address SA, the column address CA, and the row address RA are received from the memory controller 20, the state machine 5 reads out defect information of all the flag areas FA provided within the block BLK including a memory cell MC to be read out, in addition to the data of the memory cell MC to be read out.

In the following readout operation, regarding whether another flag area FA is a defective area, a method of determining by majority whether another flag area FA is a defective area in the flag area FA in which its own defective area is not “C” is adopted.

Hereinafter, a readout object is set to a memory cell MC (hereinafter, memory cell MC_{read}) within the block unit BU3.

2.1 Memory Controller 20

Next, the operations of the memory controller 20 after the defect information of the flag areas FA0 to FA3 is received from the state machine 5 will be described with reference to (a) of FIG. 11. As an example, the case of FIG. 10 is used. That is, the memory controller 20 issues a readout request to the state machine 5 (S30), and then receives readout data and defect information from the state machine 5 (S31).

Next, the memory controller 20 checks the data of the memory cell MC of a flag area FA_N (N is an integer equal to or greater than 0) of a block unit BU_N (S32).

As a result of step S32, when the data retained in the memory cell MC provided in the flag area FA_N of the block unit BU_N is not in an “E” level (that is, good) (S33, NO), the block unit BU_N is determined to be a defective area (S34).

Next, the memory controller 20 confirms whether all the block units BU are checked (S35). According to FIG. 10, when block units BU_{—}0 to BU_{—}3 are all checked (S35, YES), it is checked whether a flag area FA_M (M is an integer equal to or greater than 0), disposed in the block unit BU_N in which the data retained in the memory cell MC provided in the flag area FA is determined to be in an “E” level, is a defective area (S36).

When the data retained in the memory cell MC provided in the flag area FA_M is not in an “E” level, that is, is in a “C” level (S37, YES), the block unit BU_N corresponding to the flag area FA_M is determined to be a defective area (S38).

According to FIG. 10, the memory controller 20 determines that the block unit BU3 is a defective area on the basis of the data retained in the flag area FA3 provided in any of the block units BU0 to BU2.

Thereafter, when the memory controller 20 checks all the block units BU_N (S39, YES), the memory controller 20 discards readout data regarding the block unit BU_N determined to be a defective area (S40).

When all the block units BU are not checked in step S35 (S35, NO), the memory controller 20 counts +1 to N, and the flow proceeds to an operation of step S32 with respect to the next block unit BU (S41).

In addition, when all the block units BU are not checked in step S39 (S39, NO), the memory controller 20 counts +1 to M, and the flow proceeds to an operation of step S36 with respect to the next block unit BU (S42).

In the above flow diagram, when “C” is present in even one of the block units BU0 to BU2 with respect to the flag area FA3, the block unit BU3 is determined to be a defective area, but the method is not limited thereto.

As another determination method, there is a method of performing determination by majority. Hereinafter, a description will be given in detail.

The determination method will be described in detail with reference to FIG. 10. The memory controller 20 performs a majority determination for defect information of the flag area FA3 within the block units BU0, BU1, and BU2. That is, when the flag area FA3 is a defective area based on a majority determination, the memory controller 20 may determine a corresponding block unit BU3.

In addition, when the defect information of the flag area FA3 disposed in the block unit BU3 indicates “C” in even any one of the flag areas FA3 of Xfer_S and Xfer_D, the memory controller 20 determines the block unit BU3 to be defective, and executes the above-mentioned operation of step S37.

2.2 State Machine 5

As shown in (b) of FIG. 11, when the readout operation is requested by the memory controller 20, the state machine 5 executes the operations of step S6 to step S10 described in the above-mentioned first embodiment (step S6 to step S10). The defect information which is output in step S10 is defect information of the flag areas FA0 to FA3 disposed in the block units BU0 to BU3 in FIG. 10, respectively.

3. Write Operation

3.1 Memory Controller 20

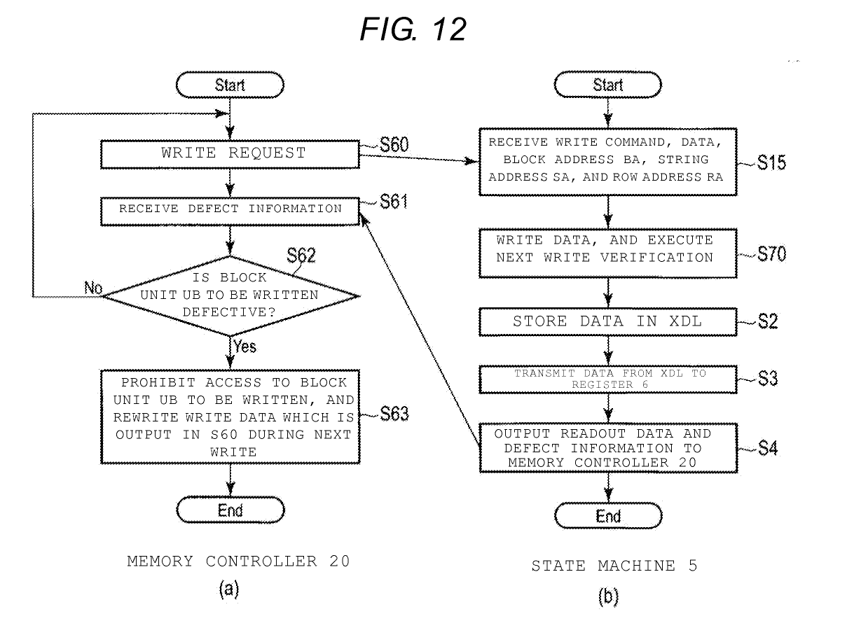

Next, operations of the memory controller 20 will be described with reference to a flow diagram of (a) of FIG. 12.

The memory controller 20 performs a write request to the state machine 5 (S60). Specifically, a write command, write data and the like are output. Thereafter, when the defect information of the flag areas FA0 to FA3 of the block units BU0 to BU3, respectively, is received from the state machine 5 (S61), the defect information of all the flag areas FA0 to FA3 is checked, and it is determined whether the block unit BU3 to be written is a defective area (S62).

As a determination method, the majority determination described in the above-mentioned readout method may be adopted, and other methods may be adopted.

As a result of the determination method, when the block unit BU3 is determined to be a defective area (S62, YES), the memory controller 20 stops writing in the block unit BU3, and then does not perform access to the block unit BU3.

Thereafter, the memory controller 20 retains write data which is once transmitted to the nonvolatile semiconductor memory device 10 in its own data storage area, and writes the data, for example, the next subsequent write operation (S63).

In addition, when the memory controller 20 determines the block unit BU3 to be a good block BLK (S62, NO), the flow proceeds to the next write operation.

3.2 State Machine 5

Next, a write operation of the state machine 5 will be described with reference to (b) of FIG. 12.

When a write request is received from the memory controller 20 (S15), the state machine 5 writes data in accordance with each address received from the memory controller 20. Next, a write verification is executed on the written data (S70).

Thereafter, the memory controller 20 executes processes of steps S2 to S4. Defect information which is output in step S4 is the defect information of the flag areas FA0 to FA3 disposed in the block unit BU0 to the block unit BU3, respectively, in FIG. 10.

### Effect According to Modified Example

In the first memory system according to the modified example, it is possible to obtain the effect of (2) in addition to the effect of (1).

(2) It is possible to improve the reliability of defect information.

That is, in the first memory system according to the modified example, each of the block units BU is provided with not only a flag area FA that retains defect information of the block unit BU, but also a flag area FA that retains defect information of another block unit BU.

Therefore, the determination of whether the block unit BU is actually a defective area can be entrusted to a good block unit BU.

This is made in view of the fact that when any of the block units BU is a good block unit BU, the tendency of an error of the defect information of the corresponding flag area FA is little.

In this manner, in the modified example, while checking the defect information of the flag area FA corresponding to the block unit BU, confirmation of whether being defective can also be made based on the defect information of the flag area FA corresponding to another block unit BU. Therefore, it is possible to improve the reliability of the defect information.

### Second Embodiment

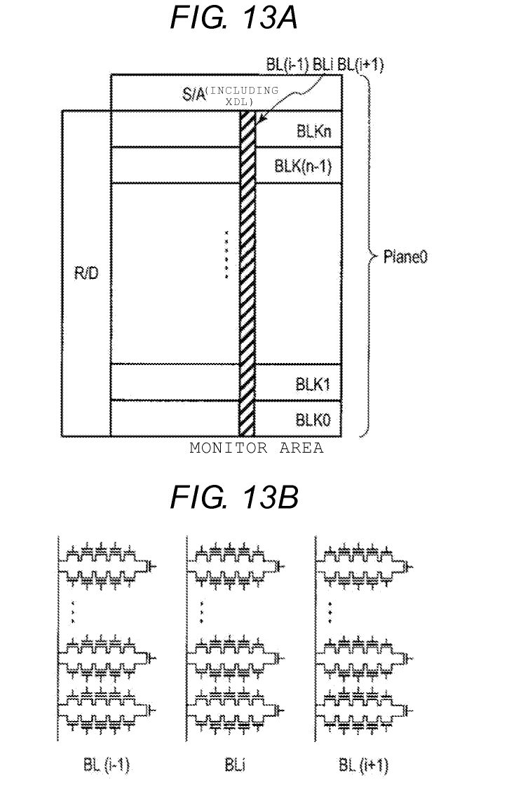

Next, a first memory system according to a second embodiment will be described with reference to FIGS. 13 to 16. The first memory system according to the second embodiment is used in performing defect management (first part) (2) after shipment mentioned above.

Although mentioned above, in the second embodiment and subsequent embodiments, a monitor area is further included in addition to the flag areas FA0 to FA3 of the first embodiment. The monitor area has a function different from that of the flag area FA. Specifically, the monitor area has a function for knowing data refresh timing of the block unit BU.

Hereinafter, in the second embodiment and subsequent embodiments, an area that retains defect information of a block BLK is called a monitor area, a memory cell MC provided in the monitor area is called a monitor cell MCmoni, and data which is read out from the monitor cell MCmoni is called monitor data

MD.

1. Conceptual Diagram of Monitor Area (First Part)

FIGS. 13A and 13B show conceptual diagrams of a monitor area (shaded portion of plane P0). FIG. 13A is a plan view of the plane P0, and FIG. 13B is an enlarged view of FIG. 13A.

As shown in FIG. 13A, the monitor area according to the second embodiment is provided, for example, so as to pass through the block BLK0 to the block BLKn. Specifically, the monitor area is constituted by, for example, a plurality of memory strings MS which are provided within a certain sub-block SB and are connected to a plurality of bit lines BL.

FIG. 13B shows a circuit diagram of a bit line BL (i−1), a bit line BLi and a bit line BL (i+1), and a memory string MS connected to these bit lines.

The monitor cell MCmoni according to the second embodiment includes memory cells MC that make up the memory string MS connected to the bit line BL (i−1), the bit line BLi, and the bit line BL (i+1). In a write operation described below, in order to monitor the tolerance of the memory cell MC, the threshold distribution of the monitor cell MCmoni is assumed to be written in a “C” (“00”) level.

That is, in this above case, three monitor data MD are collectively read out from three memory cells MCmoni. One of three memory cells MCmoni is electrically connected to the bit line BLi, another of three memory cells MCmoni electrically connected to the bit line BL (i−1), and another of three memory cells MCmoni electrically connected to the bit line BL (i+1).

Here, three bit lines BL of the bit line BL (i−1), the bit line BLi, and the bit line BL (i+1) are described as an example, the number of bit lines BL is not limited to three. That is, when the accuracy of timing at which data written in a corresponding block unit BU is refreshed is attempted to be improved, the number of monitor cells MCmoni may be increased.

In addition, each of the blocks BLK0 to BLKn (plane P0) may be determined to be a defective area in accordance with the distribution of the monitor cells MCmoni indicating defect, and a certain block BLKu (u is a natural number, where 0≦u≦n) may be determined to be a defective area.

2. With Respect to Determination of Defective Cell

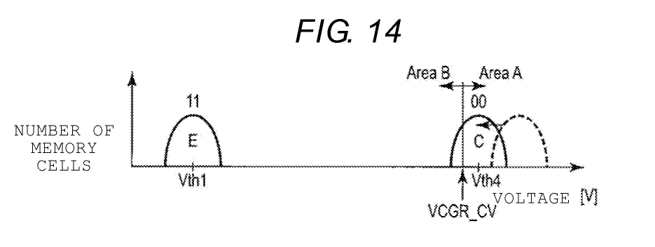

FIG. 14 shows the threshold distribution of the monitor cell MCmoni. The determination of a defective area by the state machine 5 will be described using the threshold distribution. As mentioned above, the threshold distribution of the monitor cell MCmoni is set to be “C” (“00”).

As shown in FIG. 14, when a vertical axis represents the number of memory cells MC and a horizontal axis represents a voltage, the bottom voltage of the threshold distribution of the monitor cell MCmoni is set to voltage VCG_CV.

As shown in FIG. 14, when the data retention capability of the monitor cell MCmoni lowers (dotted-line distribution=>transition to solid-line distribution), the threshold distribution falls below the voltage VCG_CV.

As described later, when more than half of, for example, cells (area B) falling below the voltage VCG_CV in the threshold distribution in a certain block BLKm or the blocks BLK0 to BLKn are present, there is a high possibility of the block BLKm or the blocks BLK0 to BLKn being defective areas. The state machine 5 counts the number of monitor cells MCmoni of the area B, and informs the memory controller 20 that the blocks BLK0 to BLKn (or block BLKm) are defective areas.

3. Write Operation (First Part)

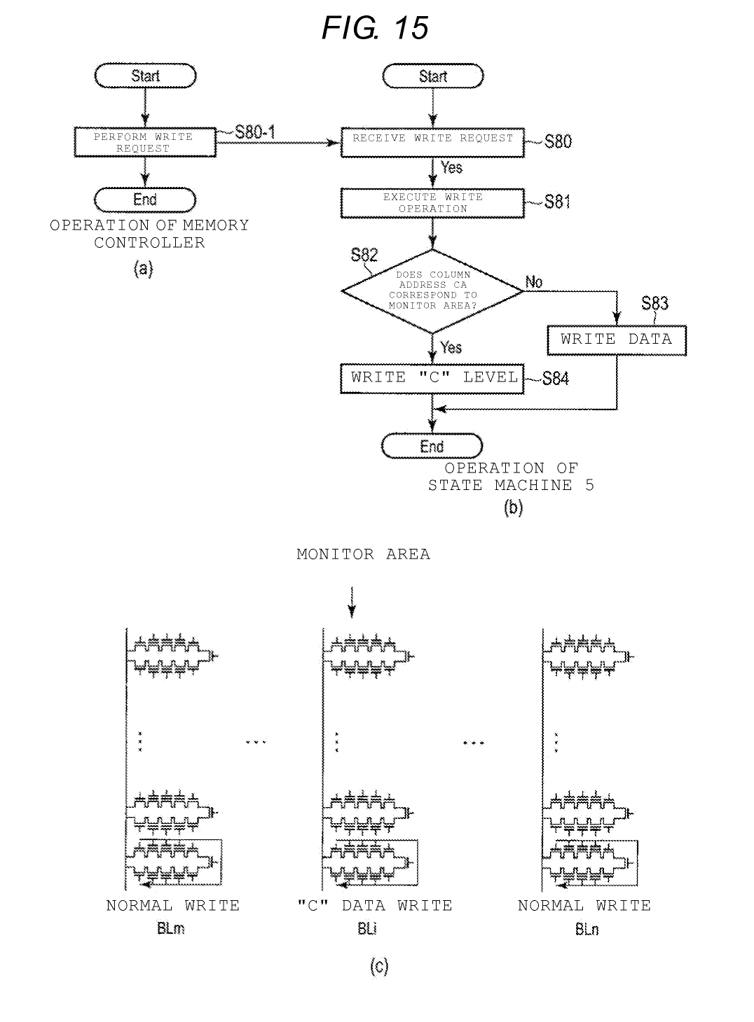

Next, write operations according to the second embodiment will be described with reference to (a) to (c) of FIG. 15. Here, (a) and (b) of FIG. 15 show write operations according to the first memory system, and (c) of FIG. 15 shows a conceptual diagram of data writing. Here, the write operation is executed on the word lines WL0 to WL7 constituting the string MS0 of the block BLK0.

3.1 Memory Controller 20

As shown in (a) of FIG. 15, the memory controller 20 performs a write request to the nonvolatile semiconductor memory device 10 (S80-1).

3.2 State Machine 5

As shown in (b) of FIG. 15, when the write request is received from the memory controller 20 (S80, YES), the state machine 5 executes a predetermined write operation in accordance with the block address BA, the string address SA, the row address RA, and the column address CA which are output from a host (S81).

Specifically, as shown in (c) of FIG. 15, data in a “C” level is written in the memory cell MC of the monitor area. Except for the monitor area, normal data is written in the memory cell MC.

4. Readout Operation (First Part)

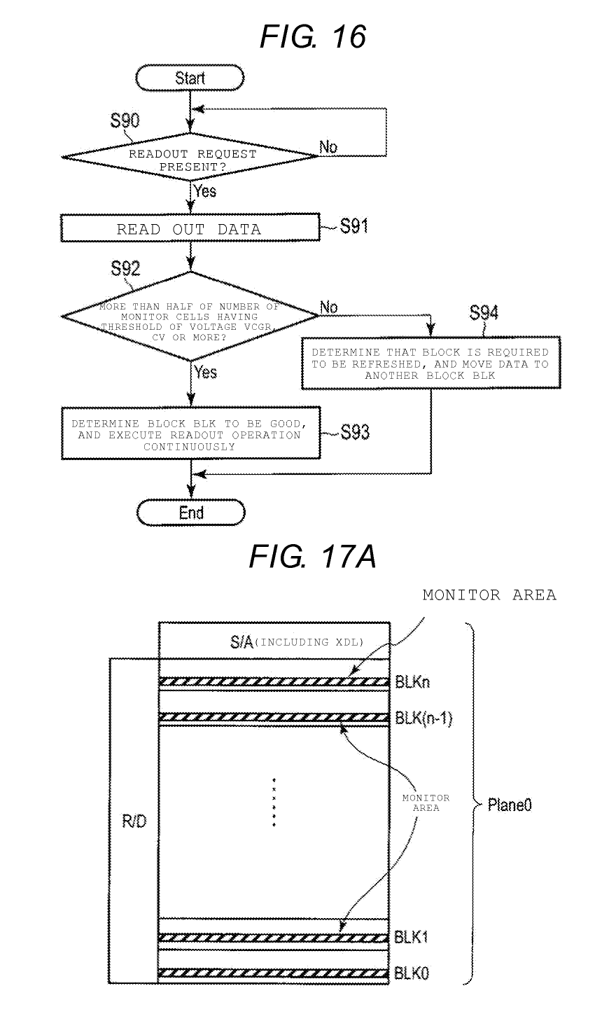

Next, readout operations of the first memory system will be described with reference to FIG. 16. In the following readout operation, the readout operation is performed at verifying voltage V_AV, voltage V_BV, and voltage V_CV, and the number of monitor cells MCmoni of which the threshold falls down from the position of a “C” level is counted.

4.1 Memory Controller 20

As shown in FIG. 16, the memory controller 20 performs a readout request to the nonvolatile semiconductor memory device 10 (S90).

4.2 State Machine 5

As shown in FIG. 16, when the readout request is issued from the memory controller 20 (S90), the state machine 5 executes data readout in page units in accordance with the block address BA, the string address SA, the column address CA, and the row address RA (S91).

Next, when viewed in a certain page, it is counted whether for example, more than half of the number of monitor cells MCmoni higher than the voltage VCG_CV are present in the monitor area (S92). As a result of the count, when the number of monitor cells MCmoni located at a threshold higher than the area A shown in FIG. 14 is more than half of the whole number of (monitor cells MCmoni) (S92, YES), the block BLK (or block unit BU) is determined to be good, and the readout operation is continued as necessary.

On the other hand, as a result of the count, when the number of monitor cells MCmoni having a threshold located below the area B shown in FIG. 14 is more than half of the whole number of (monitor cells MCmoni) (S92, NO), the state machine 5 determines the block BLK (or block unit BU) to be required to be refreshed, and moves data of this area to other good block BLK0 to block BLKm (or block unit BU) (S94).

Not only the data retained in the memory cell MC other than the monitor area, but also the data retained in the memory cell MC in the monitor area is erased by an erasing operation of the second embodiment.

### Effect According to Second Embodiment

In the first memory system according to the second embodiment, it is possible to obtain the effect of (3).

(3) It is possible to confirm the data retention capability of the user memory area with high probability.

That is, in the first memory system according to the second embodiment, the monitor cell MCmoni is disposed in the user memory area.

For this reason, the monitor cell MCmoni can monitor effects of a load or the like applied by temperature conditions, write, and erasure similar to those of actual write data. Therefore, in the monitor cell MCmoni, it also can be confirmed whether the block BLK (or block unit BU) is required to be refreshed in a state close to the actual write data.

### Third Embodiment

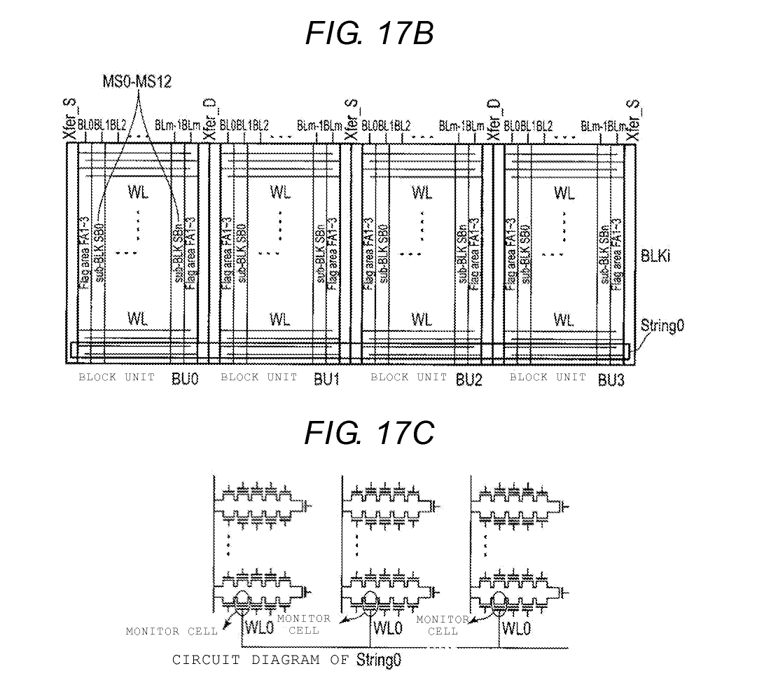

Next, a nonvolatile semiconductor memory device 10 according to a third embodiment will be described with reference to FIGS. 17A to 17C. The nonvolatile semiconductor memory device 10 according to the third embodiment is used in performing defect management (second part) (2) after shipment mentioned above.

1. Conceptual Diagram of Monitor Area (Second Part)

FIGS. 17A to 17C show conceptual diagrams of a monitor area (shaded portion of plane P0). FIG. 17A is a plan view of the plane P0, FIG. 17B is an enlarged view of FIG. 17A, and

FIG. 17C is a circuit diagram of an area shown by a thick frame in FIG. 17B.

As shown in FIG. 17A, a monitor area in the present embodiment is provided in each of the blocks BLK0 to block BLKn, and specifically, is disposed so as to extend along a plurality of block units BU constituting each of the blocks BLK. In other words, the monitor area is formed toward a page direction.

FIG. 17B shows a plan view focusing on a block BLKu. As described in the first embodiment, the block units BU0 to BU3 are also included within the block BLKu. The memory cell MC0 within the memory string MS0 in each of the block units BU0 to BU3 is set to a monitor area.

Specifically, as shown in FIG. 17C, the memory cell MC0 which is connected to the word line WL0 and is formed in a page direction is the monitor cell MCmoni.

In the present embodiment, the threshold distribution of a “C” level (“00”) is written in the monitor cell MCmoni.

2. Write Operation (Second Part)

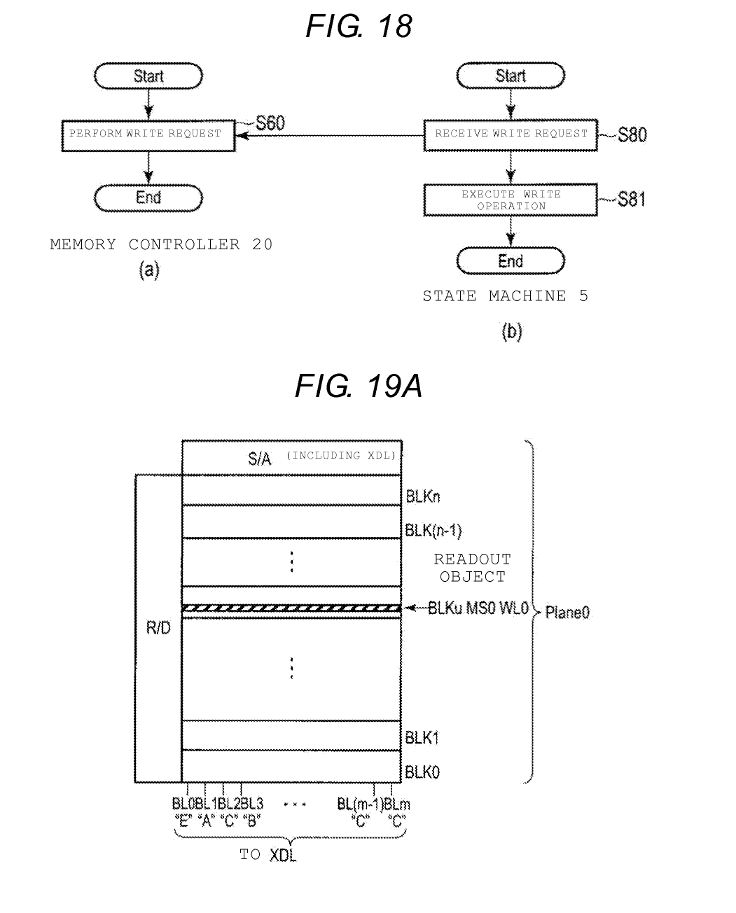

Next, a write operation of a first memory system according to the present embodiment will be described with reference to (a) and (b) of FIG. 18.

2.1 Memory Controller 20

As shown in (a) of FIG. 18, an operation of step S60 is executed. In the third embodiment, in step S60, the memory controller 20 outputs the block address BA, the string address SA, the column address CA, and data to the state machine 5.

In this case, when the string address SA and the row address RA indicate the memory string MS0 and the word line WL0, the memory controller 20 transmits “00” (C level) data as corresponding data.

On the other hand, when the string address SA and the row address RA indicate other than the memory string MS0 and the word line WL0, the memory controller 20 transmits normal data as corresponding data.

2.2 State Machine

As shown in (b) of FIG. 18, when a write request is issued from the memory controller 20, operations of steps S80 and S81 are executed.

Specifically, “00” data is written in the memory cell MC corresponding to the memory string MS0 and the word line WL0 on the basis of the address and the data transmitted from the memory controller 20, and normal data is written in memory cells MC other than those.

3. Readout Operation and Write Verifying Operation

The write operation in the present embodiment is the same as “readout operation and write verifying operation (first part)” in the above-mentioned second embodiment, and thus the description thereof will be omitted.

### Effect According to Third Embodiment

In the first memory system according to the third embodiment, it is possible to obtain the effect of (3), and to further increase the effect of (3).

That is, in the third embodiment, the monitor area is disposed in a page direction. Therefore, for example, even when only one monitor cell MCmoni is present in each memory string MS0, the defect state of the block BLK can be confirmed with a high level of accuracy.

This is because the number of bit lines BL passing through the block BLK is large, and thus a large number of monitor cells MCmoni can be provided.

The reason why the monitor cell MCmoni is set to the word line WL0 of the memory string MS0 is that initial access of both read and write of data is the memory string MS0 of each block BLK and the word line WL0 in the write operation and the readout operation. That is, as long as initial data is read out, it is possible to immediately confirm whether the block BLK is required to be refreshed.

In the third embodiment, the state machine 5 writes “00” data in the memory string MS0 and the memory cell MC of the word line WL0 in accordance with the control of the memory controller 20, but the method is not limited thereto.

That is, places in which “00” data is written may be the memory string MS to be initially accessed and the memory cell MC corresponding to the address of the word line WL in each block unit BU, and are not limited to the memory string MS0 and the memory cell MC of the word line WL0.

### Second Modified Example

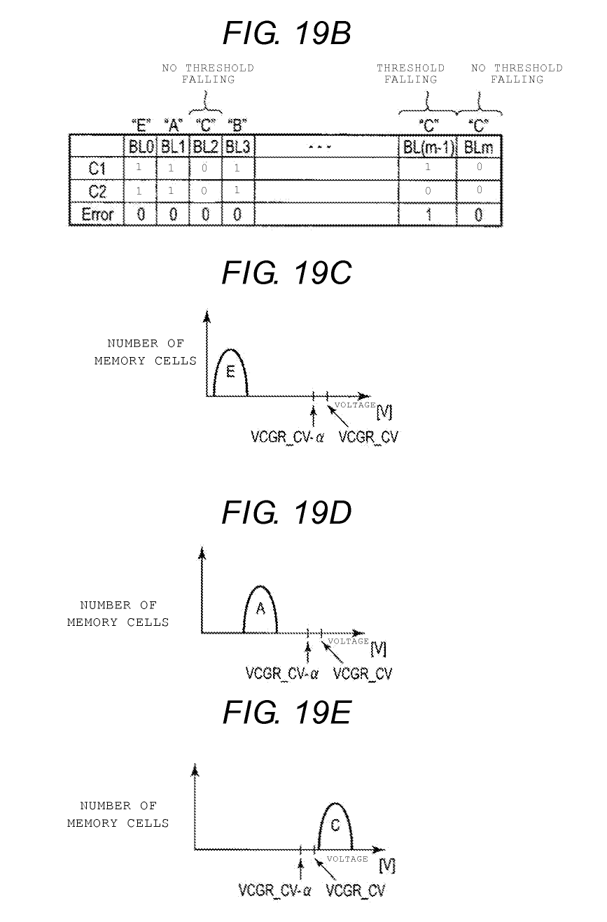

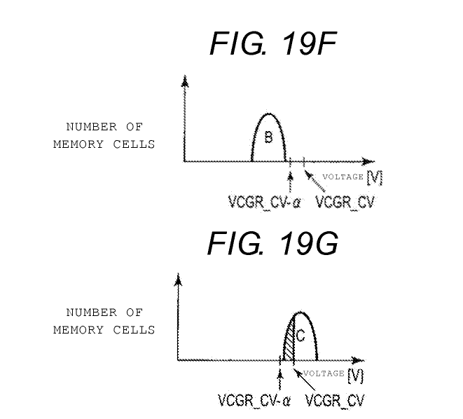

Next, a first memory system according to a modified example of the third embodiment (hereinafter, second modified example) will be described with reference to FIGS. 19A to 19G. The first memory system according to the second modified example is not provided with the flag area FA and the monitor cell MCmoni, and is used in ascertaining whether the block BLK (or block unit BU) is required to be refreshed using the actual write data.

Specifically, the above-mentioned example is different from the second embodiment, in that without being provided with the flag area FA and the monitor cell MCmoni, the number of memory cells MC with decreased retention capability in user data (“00”) is counted, and the block BLK (or any of the block units BU0 to BU3) is determined to be a defective area in accordance with a count value.

In a specific method of ascertaining a defect state, the number of memory cells MC is counted in which an XOR arithmetic operation result between user data read out at voltage VCG_CV and user data read out at voltage VCG_CV_{—α} (<voltage VCG_CV) is, for example, “1”, and when the result has a specified value or more, the block BLK (or block units BU0 to BU3) is determined to be an area which is required to be refreshed.

1. Conceptual Diagram of Arithmetic Operation Using Readout Data and Expectation Value

An arithmetic operation using readout data and an expectation value will be described with reference to FIGS. 19A to 19G.

In the following, it is assumed in FIG. 3 that “0” data is read out from the memory cell MC when the threshold voltage of the memory cell MC is located at a “C” level, and “1” data is read out from the memory cell MC located at other levels, that is, an “E” level to a “B” level.

An expression “0 data is read out from the memory cell MC” as above means that a voltage of a sense node in the sense amplifier 3 becomes a first voltage corresponding to “0” data. On the other hand, an expression “1 data is read out from the memory cell MC” as above means that a voltage of a sense node in the sense amplifier 3 becomes a second voltage corresponding to “1” data. The first voltage is higher than the second voltage.

FIG. 19A is a conceptual diagram illustrating data which is read out in the bit line BL, and FIG. 19B is a table illustrating results (“1”, or “0”: denoted as C1 and C2 in the drawing) which are read out at a predetermined verifying voltage (here, voltage VCGR_CV and voltage VCGR_CV_{-α}) for each bit line BL, and XOR arithmetic operation results between C1 and C2.

Further, FIGS. 19C to 19G show the threshold distribution of data which is read out from the bit lines BL0 to BL3, BL (m−1), and BLm.

As shown in FIG. 19A, the block BLKu, the memory string MS0, and the word line WL0 are to be read out. In this case, any data of “1” or “0” is read out in the bit lines BL0 to BLm.

As shown in FIG. 19B, a vertical axis represents data (hereinafter, data C1) which is read out at voltage VCG_CV by the sense amplifier 3, data (hereinafter, data C2) which is read out at voltage VCG_CV_{—α}, by the sense amplifier 3, and results (Error) obtained by performing an XOR arithmetic operation between data C1 and data C2, and a horizontal axis represents the bit line BL. The arithmetic operation results are stored in XDL (cache circuit that exchanges data with the register 6) within the sense amplifier 3.

Even when the memory cell MC having threshold voltages as shown in FIGS. 19C to 19D and 19F performs a readout operation at any of the voltage VCG_CV and the voltage VCG_CV_{—α}, data C1 and C2 are “1”. Therefore, the XOR arithmetic operation result between the data C1 and the data C2 becomes “0”.

In addition, when the memory cell MC having a threshold voltage as shown in FIG. 19E performs a readout operation at any of the voltage VCG_CV and the voltage VCG_CV_{—α}, both the data C1 and the data C2 are “0”. Therefore, the XOR arithmetic operation result between the data C1 and the data C2 becomes “0”.

On the other hand, when the memory cell MC having a threshold voltage as shown in FIG. 19G performs a readout operation at the voltage VCG_CV_{—α}, the data C2 becomes “0”, but when the memory cell performs a readout operation at the voltage VCG_CV, the data C1 becomes “1”. Therefore, the XOR arithmetic operation result between the data C1 and the data C2 becomes “1”.

The arithmetic operation results are stored in the XDL in any case of “0” and “1”, and then are transmitted to the register 6. Thereafter, the results are output to a host by the state machine 5.

2. Readout Operation

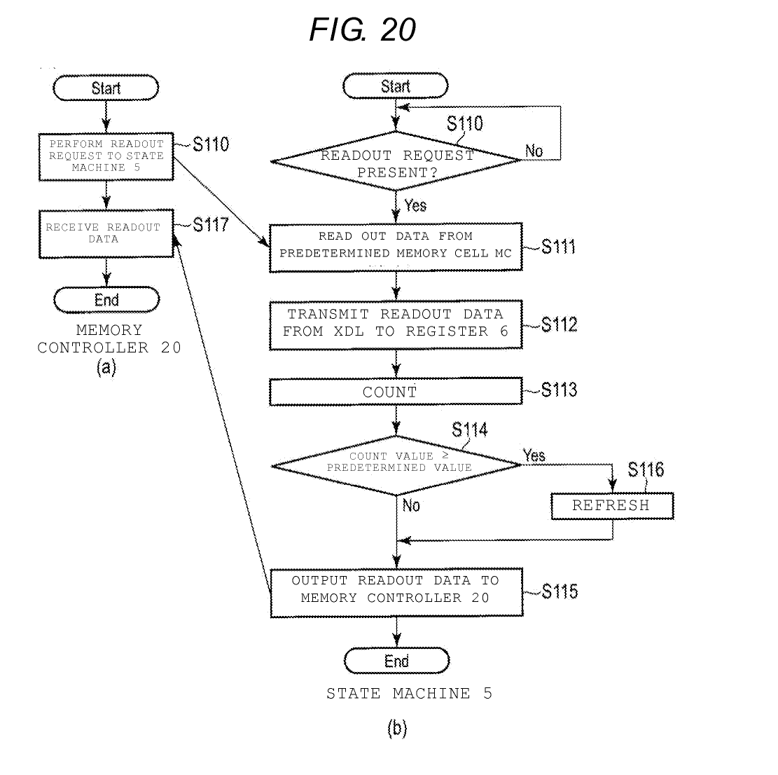

Next, operations of the first memory system during the readout operation will be described with reference to (a) and (b) of FIG. 20.

2.1 Memory Controller 20

The memory controller 20 performs a readout request to the state machine 5 (S110). Thereafter, readout data is received from the state machine 5 (S117).

2.2 State Machine 5

When the readout request is issued from a host, the state machine 5 reads out a predetermined memory cell MC in accordance with the received block address BA, string address SA, column address CA, and row address RA (S111).

Thereafter, the state machine 5 transmits readout data through the XDL to the register 6 (S112), and counts “1” data within the register 6 (S113).

As a result of the count, when the count value is a predetermined value or less (S114, NO), the state machine 5 outputs the readout data to the memory controller 20 (S115).

On the other hand, when the count value is a predetermined value or more (S114, YES), the state machine 5 determines a target block BLK (or block unit BU) to be required to be refreshed (S116).

Specifically, after data of the block BLK (or block unit BU) is transmitted to another area, the block BLK (or block unit BU) is refreshed. Next, an operation of step S115 is executed.

Here, a description is given focusing on the memory cell MC having a threshold voltage in a “C” level, the focusing memory cell MC is not limited thereto. That is, in addition to the XOR arithmetic operation results for the memory cell MC of a “C” level, defect management may be performed using, for example, XOR arithmetic operation results for the memory cell MC having a threshold voltage (for example, “A” level) lower than the level.

In this case, the degree of freedom for the defect management of the state machine 5 increases. That is, the defect management may be performed using the arithmetic operation results of the memory cell MC having a threshold voltage of either the “C” level or the “A” level, and the defect management may be performed using the arithmetic operation results of both levels.

In a specific arithmetic operation method for the memory cell MC of an “A” level as shown in FIG. 19D, readout voltage VCG_AV and voltage VCG_AV_{—α} are prepared, an XOR arithmetic operation is performed on a value which is read out at each voltage.

In addition, there are the following three reasons in the use of the memory cell MC of an “A” level.

Firstly, the threshold of the memory cell MC having an “A” level and a “B” level as shown in FIGS. 19D to 19F among the levels of the memory cell MC of which the threshold seldom falls down as shown in FIG. 19E, may tend to fall down.

Secondly, deviation may occur in the deterioration of the memory cell MC for each block BLK.

Thirdly, there may be a case where it is not determined to be defective no matter how much time passes, due to a value for determination to be defective in step S113 (case where a “predetermined value” shown in S114 is excessively large, or the like).

In this manner, the defect management may be performed using the memory cell MC having a plurality of threshold voltages.

### Effect According to Second Modified Example

In the first memory system according to the second modified example, it is also obtain the above effects of (3) and (4), and to further improve efficiency in (3).

That is, in the second modified example, actual write data within the user memory area is also used. Therefore, it is possible to obtain the same effect as that in the third embodiment.

In the effect of (3), it is possible to ascertain the defect state of the block BLK more efficiently. This is because not only the defect state of the memory cell MC retaining one piece of data (“C” level) is ascertained, but also the retention capability of the memory cell MC retaining other pieces of data (for example, “A” level) is confirmed.

There are three reasons stated above, for example, in additionally using the memory cell MC retaining an “A” level as an object of the monitor cell. In this manner, a plurality of memory cells MC are used as an object of the monitor cell, and thus it is possible to finely ascertain the defect state of the block BLK.

### Third Modified Example

Next, a first memory system according to a modified example of the third embodiment (hereinafter, third modified example) will be described. The first memory system according to the third modified example is different from those in the second embodiment and the second modified example, in that the threshold of the memory cell MC is set from a quaternary value to a binary value (“E” level and “C” level). That is, the memory cell MC retains any value of 1-bit (“0” or “1” data).

The number of pieces of data capable of being retained by the first memory system decreases, but the number of memory cells MC of a “C” level increases. Therefore, the defect management is performed and then the number of samples increases.

### Effect According to Third Modified Example

In the first memory system according to the third modified example, it is also possible to obtain the effect of (5) in addition to the above effects of (3) and (4).

(5) It is possible to increase the number of samples.

In the first memory system according to the third modified example, the data retained in the memory cell MC within the user memory area is set to a binary value. However, even when data of any of the blocks BLK is read out unlike the third embodiment, a “C” level can be read out with half probability.

That is, it is possible to perform the defect management of uniform blocks BLK without data deviation.

### Fourth Embodiment

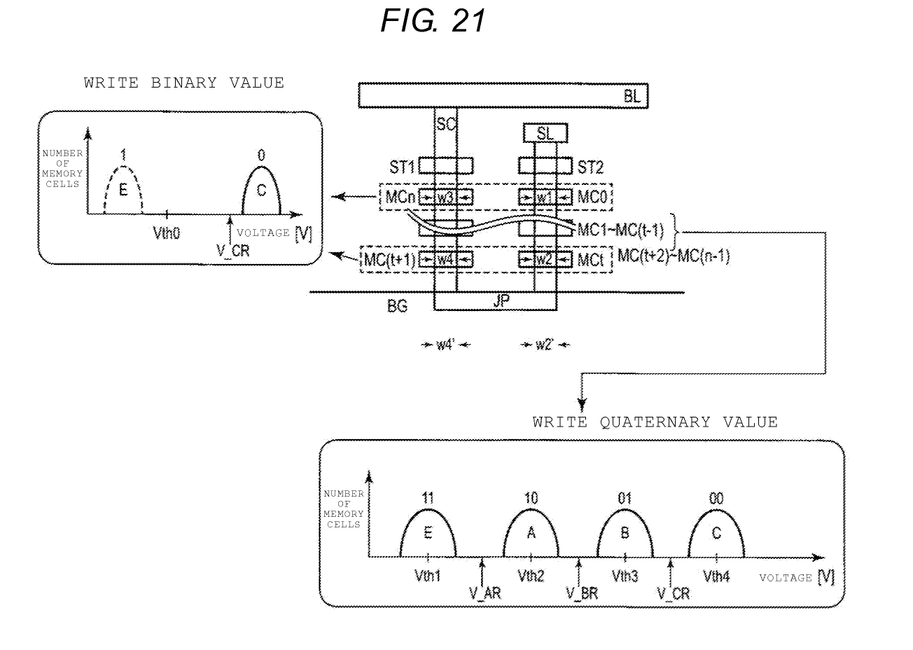

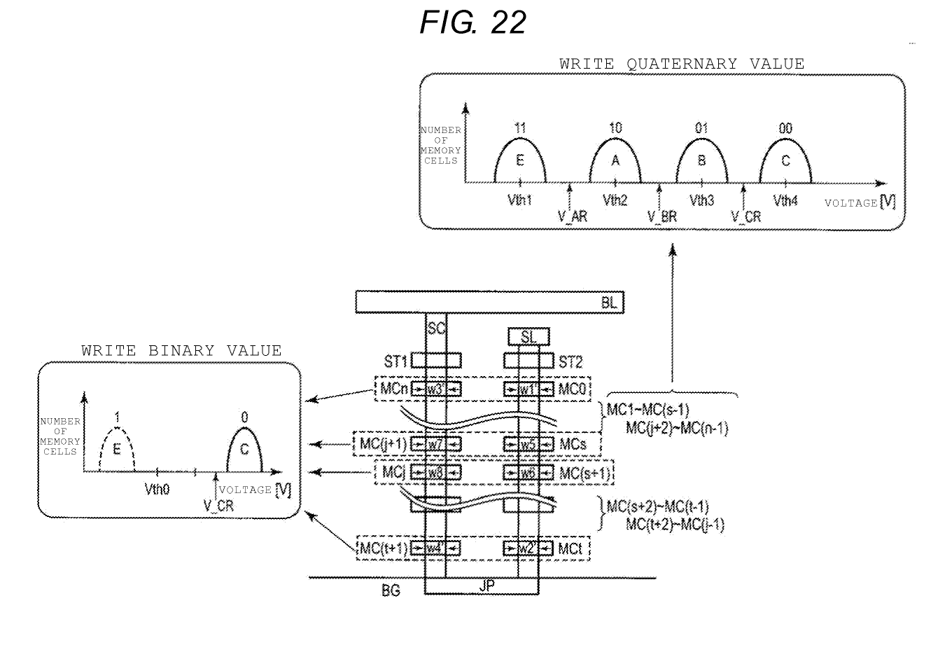

Next, a nonvolatile semiconductor memory device 10 according to a fourth embodiment will be described with reference to FIGS. 21 and 22. In the fourth embodiment, a write operation is performed at a binary value (any of “E” level or “C” level) on the memory cell MC having defect characteristics or the memory cell MC which is easily influenced by an electric field during writing.

Hereinafter, the cross-sectional view of the memory string MS will be described in separate areas of an upper layer, an intermediate layer, and a lower layer.

1. Cross-Sectional View (First Part)

FIG. 21 shows a cross-sectional view (first part) of the memory string MS. The semiconductor layer SC shown in FIG. 21 constitutes part of the memory string MS, is provided in a direction normal to the semiconductor layer BG, and tends to decrease in width in a direction from the memory cell MC of the upper layer area to that of the lower layer area.

Specifically, the width of the semiconductor layer SC passing through a memory cell MC0 is w1, and the width of the semiconductor layer SC passing through a memory cell MCt is w2 (<w1).

Similarly, the width of the semiconductor layer SC passing through a memory cell MC1 is w3, and the width of the semiconductor layer SC passing through a memory cell MC (t+1) is w4 (<w3).

Since the formation of the semiconductor layer SC is performed collectively during manufacturing, the width of the semiconductor layer SC tends to decrease toward the lower layer in this manner.

2. Cross-sectional View (Second Part)

FIG. 22 shows a cross-sectional view (second part) of the memory string MS. FIG. 21 is different from FIG. 22, in that the formation of the semiconductor layer SC is performed twice. That is, first, the memory string MS of the lower layer area is formed. Next, the memory string MS of the upper layer area is stacked on the memory string MS of the lower layer area.

Specifically, after polysilicon functioning as the word line WL is first stacked and thereafter the formation of the semiconductor layer SC is performed, the semiconductor layer SC is embedded. The memory string MS of the lower layer area is formed by such a process. Thereafter, the same process is performed on the upper layer area as well. Thereby, the memory string MS shown in FIG. 22 is formed.

Since the formation of the semiconductor layer SC is performed twice in this manner, the width of the semiconductor layer SC passing through the memory cell MC located at the intermediate layer area is different from that in FIG. 21. Specifically, the width of a memory cell MCs of the upper layer area is w5, whereas the width of a memory cell MC (s+1) of the lower layer area is w6 (>w5). In addition, the width of a memory cell MCj is w8, whereas the width of a memory cell MC (j+1) is w7 (>w8).

3. Data Writing Method

Next, the memory cell MC in which data writing is performed with a binary value and the memory cell MC in which the data writing is performed with a quaternary value will be described with reference to FIGS. 21 and 22.

In FIGS. 21 and 22, data writing with a binary value is performed on the memory cell MC surrounded by a dashed box.

In addition, in FIGS. 21 and 22, data writing by a quaternary value is performed on other memory cells MC.

### Effect According to Fourth Embodiment

In the first memory system according to the fourth embodiment, it is possible to obtain the following effect of (6).

(6) It is possible to improve operation reliability.

That is, in the first memory system according to the fourth embodiment, the proper application of a voltage can be made in accordance with the characteristics of the memory cell MC which vary as a result of how a hole in which the semiconductor layer SC is formed was processed.

That is, when the memory cell MC has a semiconductor layer SC of a large diameter, write, readout, and erasure of data are not able to be performed suitably as compared to other memory cells MC because it is more difficult to apply an electric field thereto.

On the other hand, when the memory cell MC has a semiconductor layer SC of a small diameter, over-programming may occur, for example, during data writing because electric field may be excessively applied thereto.

In order to solve such a problem, data writing with a “binary” value is performed on the memory cell MC having a large diameter and the memory cell MC having a small diameter.

Because write, readout, erasure and the like of data of a binary value can be performed more easily than data of a quaternary value, even in the case of, for example, over-programming, data of a binary value of “0” or “1” can be retained. Thus, there is no problem in the use of data.

In addition, in the first embodiment to the fourth embodiment mentioned above, the memory controller 20 performs the transfer of data, the defect management of the block BLK, the issue of a command, and the like, but these functions may be performed by a host (not shown). Also, the state machine 5 can execute the operations according to the above-mentioned first to fourth embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory cell array including a plurality of block units that share a plurality of bit lines, each block unit including a plurality of memory cells for storing user data and at least one memory cell for storing flag data indicating whether the block unit is defective;
a control unit configured to read the flag data from a block unit during a read operation or a write operation on the block unit, and when the flag data indicates the block unit is defective, discontinue the read operation and the write operation on the block unit.

2. The device according to claim 1, wherein the data that are read from the memory cells of the block unit as a result of the read operation are discarded.

3. The device according to claim 1, wherein the write data to be stored in the memory cells of the block unit in response to the write operation are not written in the memory cells.

4. The device according to claim 1, wherein each one of a plurality of memory cells electrically connected in series between one of the bit lines and a source line includes the flag data.

5. The device according to claim 4, wherein the flag data of all of the memory cells indicate that the block unit is defective.

6. The device according to claim 4, wherein the flag data of all of the memory cells indicate that the block unit is not defective.

7. The device according to claim 1, wherein one memory cell in each page unit of memory cells is reserved as a monitor memory cell and during a write operation to a page unit of memory cells, the control unit writes dummy data to the monitor memory cell of the page unit.

8. The device according to claim 7, wherein during a read operation on the page unit, the control unit compares a threshold voltage of the monitor memory cell with a first voltage level and performs a refresh operation on the page unit if the threshold voltage of the monitor memory cell is less than the first voltage level.

9. The device according to claim 1, wherein the memory cells include at least one memory string including a first memory cell configured to store data having one of 2^{m} levels and a second memory cell configured to store data having one of 2ⁿ levels, where m and n are different integers greater than or equal to 1.

10. The device according to claim 1, wherein a block unit and a word line are selected during a read operation or a write operation, and all of the memory cells of the selected block unit are read during the read operation and less than all of the memory cells of the selected block unit are written to during the write operation.

11. A nonvolatile semiconductor memory device comprising:
a plurality of block units of memory cells that share a plurality of bit lines, each block unit including a plurality of memory strings, each memory string including a plurality of memory cells connected in series between a respective one of the bit lines and a source line; and
a control unit configured to select a block unit and a word line during a during a read operation or a write operation,
wherein all of the memory cells of the selected block unit are read during the read operation and less than all of the memory cells of the selected block unit are written to during the write operation.

12. The device according to claim 11, wherein the control unit configured to select a block unit during an erasing operation and none of the memory cells in at least one of the memory strings of the selected block unit are erased during the erasing operation.

13. The device according to claim 11, wherein the block units include first and second block units and the memory strings in each block unit include a first memory string having one or more memory cells storing flag data indicating whether the first block unit is defective and a second memory string having one or more memory cells storing flag data indicating whether the second block unit is defective.

14. The device according to claim 13, wherein when a read operation or a write operation is performed for the first block unit, the control unit reads out the flag data indicating whether the first block unit is defective from the second block unit and when a read operation or a write operation is performed for the second block unit, the control unit reads out the flag data indicating whether the second block unit is defective from the first block unit.

15. The device according to claim 11, wherein the memory strings in each block unit include flag data memory strings, one of each of the block units, indicating whether the corresponding block unit is defective, and when a read operation or a write operation is performed for a block unit, the control unit reads out the flag data indicating whether the block unit is defective from other block units and determines that the block unit is defective if a majority of the other units indicates that the block unit is defective.

16. A method of performing an operation on a nonvolatile semiconductor memory device including a plurality of block units of memory cells that share a plurality of bit lines, each block unit including a plurality of memory strings, each memory string having a plurality of memory cells connected in series between a respective one of the bit lines and a source line, said method comprising:
selecting a block unit and determining a threshold voltage level of a memory cell of one of the memory strings in the selected block unit;
determining whether or not one of the block units is defective based on the threshold voltage level.

17. The method of claim 16, wherein the selected block unit is determined to be defective or not based on the threshold voltage level.

18. The method of claim 16, wherein a block unit different from the selected block unit is determined to be defective or not based on the threshold voltage level.

19. The method of claim 16, further comprising:
reserving one memory cell in each page unit of memory cells as a monitor memory cell;
during a write operation to a page unit of memory cells, writing dummy data to the monitor memory cell of the page unit; and
during a subsequent read operation on the page unit, comparing a threshold voltage of the monitor memory cell with a first voltage level and performing a refresh operation on the page unit if the threshold voltage of the monitor memory cell is less than the first voltage level.

20. The method according to claim 16, further comprising:
during a write operation, storing data having one of 2^{m} levels to one of the memory cells and data having one of 2ⁿ levels to another one of the memory cells, where m and n are different integers greater than or equal to 1.
